(19) United States
(12) Patent Application Publication
(10) Pub. No.: US 2026/0020432 A1
(43) Pub. Date: Jan. 15, 2026

(54) Light-Emitting Device, Display Substrate, and Display Apparatus

(71) Applicant: BOE TECHNOLOGY GROUP CO., LTD., Chaoyang District, Beijing (CN)

(72) Inventors: Xiaojin Zhang, Beijing (CN); Haiyan Sun, Beijing (CN); Xinghua Liu, Beijing (CN)

(21) Appl. No.: 18/992,320

(22) PCT Filed: Apr. 16, 2024
(86) PCT No.: PCT/CN2024/088123

§ 371 Date: Jan. 8, 2025

(30) Foreign Application Priority Data
May 19, 2023 (CN) 202310576692.3

(51) Int. Cl. H10K 50/12; H10K 101/30; H10K 102/00

(52) U.S. Cl. CPC H10K 50/121; H10K 2101/30; H10K 2102/351

(57) ABSTRACT

A light-emitting device includes a first electrode, at least one first light-emitting layer, at least one second light-emitting layer, at least one third light-emitting layer and a second electrode which are sequentially stacked. In a first light-emitting layer, a second light-emitting layer and a third light-emitting layer, at least the second light-emitting layer includes a sensitizing material; the mass concentration X2 of the sensitizing material in the material of the second light-emitting layer and the mass concentration X1 of the sensitizing material in the material of the first light-emitting layer meet the following conditions: X2≥X1 and X1≥0; and the mass concentration X2 of the sensitizing material in the material of the second light-emitting layer and the mass concentration X3 of the sensitizing material in the material of the third light-emitting layer meet the following conditions: X2≥X3 and X3≥0.

### CROSS-REFERENCE TO RELATED APPLICATIONS

This application is the United States national phase of International Patent Application No. PCT/CN2024/088123, filed Apr. 16, 2024, and claims priority to Chinese Patent Application No. 202310576692.3, filed May 19, 2023, the disclosures of which are hereby incorporated by reference in their entireties.

### BACKGROUND OF THE INVENTION

### Field of the Invention

The present disclosure relates to the field of display technologies, and in particular, to a light-emitting device, a display substrate and a display apparatus.

### Description of Related Art

Organic light-emitting diode (OLED) display apparatuses have been listed as the next generation display technology with great development prospects due to thinness, lightness, wide viewing angle, active luminescence, continuously adjustable light color, low cost, fast response speed, low energy consumption, low driving voltage, wide operating temperature range, simple production process, high luminous efficiency, being capable of flexible display, and other advantages.

### SUMMARY OF THE INVENTION

In an aspect, a light-emitting device is provided. The light-emitting device includes a first electrode, at least one first light-emitting layer, at least one second light-emitting layer, at least one third light-emitting layer and a second electrode that are disposed sequentially. In a first light-emitting layer, a second light-emitting layer and a third light-emitting layer, at least the second light-emitting layer includes a sensitizing material. A mass concentration X2 of the sensitizing material in a material of the second light-emitting layer and a mass concentration X1 of the sensitizing material in a material of the first light-emitting layer satisfy: X2≥X1 and X1≥0. The mass concentration X2 of the sensitizing material in the material of the second light-emitting layer and a mass concentration X3 of the sensitizing material in a material of the third light-emitting layer satisfy: X2≥X3 and X3≥0.

In some embodiments, the mass concentration X2 of the sensitizing material in the material of the second light-emitting layer satisfies: 20%≤X2≤70%.

In some embodiments, the mass concentration X2 of the sensitizing material in the material of the second light-emitting layer and the mass concentration X1 of the sensitizing material in the material of the first light-emitting layer satisfy: 0≤(X2−X1)≤15%.

In some embodiments, the mass concentration X2 of the sensitizing material in the material of the second light-emitting layer and the mass concentration X3 of the sensitizing material in the material of the third light-emitting layer satisfy: 0≤(X2−X3)≤15%.

In some embodiments, the mass concentration X1 of the sensitizing material in the material of the first light-emitting layer satisfies: 3%≤X1≤50%; and/or the mass concentration X3 of the sensitizing material in the material of the third light-emitting layer satisfies: 3%≤X3≤50%.

In some embodiments, in the first light-emitting layer, the second light-emitting layer and the third light-emitting layer, at least the second light-emitting layer includes a guest material. A mass concentration Y2 of the guest material in the material of the second light-emitting layer and a mass concentration Y1 of the guest material in the material of the first light-emitting layer satisfy: Y2≥Y1 and Y1≥0. The mass concentration Y2 of the guest material in the material of the second light-emitting layer and a mass concentration Y3 of the guest material in the material of the third light-emitting layer satisfy: Y2≥Y3 and Y3≥0.

In some embodiments, the mass concentration Y2 of the guest material in the material of the second light-emitting layer satisfies: 0.1%≤Y2≤5%.

In some embodiments, the sensitizing material included in the second light-emitting layer is a second sensitizing material, and the guest material included in the second light-emitting layer is a second guest material. The second light-emitting layer further includes a second host material and a second stabilizing material. A difference between a triplet state of at least one of the second host material, the second sensitizing material and the second guest material and a triplet state of the second stabilizing material is less than or equal to 0.3 eV. An overlapping area between a normalized emission spectrum of at least one of the second host material, the second sensitizing material and the second guest material and a normalized absorption spectrum of the second stabilizing material is greater than or equal to 30% of an integrated area of the normalized absorption spectrum of the second stabilizing material.

In some embodiments, a mass concentration of the second stabilizing material in the material of the second light-emitting layer is less than or equal to 5%.

In some embodiments, a wavelength of a photoemission spectrum peak of the second host material is less than a wavelength of a photoemission spectrum peak of the second sensitizing material, the wavelength of the photoemission spectrum peak of the second sensitizing material is less than a wavelength of a photoemission spectrum peak of the second stabilizing material; and a wavelength of a photoemission spectrum peak of the second guest material is less than the wavelength of the photoemission spectrum peak of the second stabilizing material.

In some embodiments, the sensitizing material included in the third light-emitting layer is a third sensitizing material; the guest material included in the second light-emitting layer is a second guest material; and the sensitizing material included in the first light-emitting layer is a first sensitizing material. An overlapping area between a normalized emission spectrum of the third sensitizing material and a normalized absorption spectrum of the second guest material is greater than or equal to 60% of an integrated area of the normalized absorption spectrum of the second guest material. And/or an overlapping area between a normalized emission spectrum of the first sensitizing material and a normalized absorption spectrum of the second guest material is greater than or equal to 60% of an integrated area of the normalized absorption spectrum of the second guest material.

In some embodiments, an overlapping area between a normalized emission spectrum of the second guest material and a normalized emission spectrum of the light-emitting device is greater than or equal to 80% of an integrated area of the normalized emission spectrum of the second guest material.

In some embodiments, the sensitizing material included in the second light-emitting layer is a second sensitizing material, and an overlapping area between a normalized emission spectrum of the second sensitizing material and the normalized absorption spectrum of the second guest material is greater than or equal to 60% of an integrated area of the normalized absorption spectrum of the second guest material.

In some embodiments, the sensitizing material included in the first light-emitting layer is a first sensitizing material; and the first light-emitting layer further includes a first host material, a first stabilizing material and a first guest material. A difference between a triplet state of at least one of the first host material, the first guest material and the first sensitizing material and a triplet state of the first stabilizing material is less than or equal to 0.3 eV. And/or an overlapping area between a normalized emission spectrum of at least one of the first host material, the first guest material and the first sensitizing material and a normalized absorption spectrum of the first stabilizing material is greater than or equal to 30% of an integrated area of the normalized absorption spectrum of the first stabilizing material.

In some embodiments, the sensitizing material included in the second light-emitting layer is a second sensitizing material; the second light-emitting layer further includes a second host material; the sensitizing material included in the third light-emitting layer is a third sensitizing material; and the third light-emitting layer further includes a third host material. A highest occupied molecular orbital energy level of the first host material is HOMO(A), a highest occupied molecular orbital energy level of the first sensitizing material is HOMO(B), a highest occupied molecular orbital energy level of the second host material is HOMO(E), a highest occupied molecular orbital energy level of the second sensitizing material is HOMO(F), a highest occupied molecular orbital energy level of the third host material is HOMO(J), and a highest occupied molecular orbital energy level of the third sensitizing material is HOMO(K); and HOMO(A), HOMO(B), HOMO(E), HOMO(F), HOMO(J) and HOMO(K) satisfy:

$$\vert HOMO ( A ) \vert \leq \vert HOMO ( B ) \vert , \vert HOMO ( E ) \leq \vert HOMO ( F ) \vert ,$$

$$\vert HOMO ( J ) \vert \leq \vert HOMO ( K ) \vert , \vert HOMO ( A ) \vert \leq \vert HOMO ( F ) \vert ,$$

$$\vert HOMO ( E ) \vert \leq \vert HOMO ( K ) \vert , \vert HOMO ( A ) - HOMO ( E ) \vert \leq 0.25 eV ,$$

$$\vert HOMO ( E ) - H O M O ( J ) \vert \leq 0.25 eV , \vert HOM O ( A ) - H O M O ( B ) \vert \leq 0.25 eV ,$$

$$\vert HOMO ( E ) - H O M O ( F ) \vert \leq 0.25 eV , \vert HOM O ( J ) - H O M O ( K ) \vert \leq 0.25 eV ,$$

$$\vert HOMO ( A ) - H O M O ( F ) \vert \leq 0.25 eV and$$

$$\vert HOMO ( E ) - H O M O ( K ) \vert \leq 0.25 eV .$$

In some embodiments, a triplet state of the first host material is T1(A), a triplet state of the first sensitizing material is T1(B), a triplet state of the second host material is T1(E), a triplet state of the second sensitizing material is T1(F), a triplet state of the third host material is T1(J), and a triplet state of the third sensitizing material is T1(K); and T1(A), T1(B), T1(E), T1(F), T1(J) and T1(K) satisfy:

$$\vert T 1 ( A ) - T 1 ( E ) \vert \leq 0.15 eV , \vert T 1 ( E ) - T 1 ( J ) \vert \leq 0.15 eV ;$$

$$T 1 ( A ) \geq T 1 ( B ) , T 1 ( E ) \geq T 1 ( F ) and T 1 ( J ) \geq T 1 ( K ) .$$

In some embodiments, an electroluminescence amount of the second light-emitting layer is greater than or equal to 50% of a total luminescence amount of the light-emitting device.

In some embodiments, a thickness L1 of the first light-emitting layer, a thickness L2 of the second light-emitting layer and a thickness L3 of the third light-emitting layer satisfy: L2>L1 and L2>L3.

In some embodiments, a thickness L1 of the first light-emitting layer, a thickness L2 of the second light-emitting layer and a thickness L3 of the third light-emitting layer satisfy: L2≥ (L1+L3).

In some embodiments, the light-emitting device further includes an electron blocking layer located between the first electrode and the first light-emitting layer. The sensitizing material included in the first light-emitting layer is a first sensitizing material; and a triplet state of the electron blocking layer is greater than a triplet state of the first sensitizing material.

In some embodiments, the light-emitting device further includes a hole blocking layer located between the second electrode and the third light-emitting layer. The sensitizing material included in the third light-emitting layer is a third sensitizing material; and a triplet state of the hole blocking layer is greater than a triplet state of the third sensitizing material.

In some embodiments, the light-emitting device includes a plurality of light-emitting units stacked between the first electrode and the second electrode, and each light-emitting unit includes a first light-emitting layer, a second light-emitting layer and a third light-emitting layer. The light-emitting device further includes a charge generation layer disposed between two adjacent light-emitting units, and the charge generation layer is used to connect the two adjacent light-emitting units.

In another aspect, a light-emitting device is provided. The light-emitting device includes a first electrode and a second electrode that are disposed oppositely, and at least one light-emitting layer located between the first electrode and the second electrode. A material of a light-emitting layer includes a sensitizing material. In a thickness direction of the light-emitting layer and from the first electrode to the second electrode, a mass concentration of the sensitizing material in the light-emitting layer changes from small to large and then from large to small.

In some embodiments, the material of the light-emitting layer further includes a guest material; and in the thickness direction of the light-emitting layer and from the first electrode to the second electrode, a mass concentration of the guest material in the light-emitting layer changes from small to large and then from large to small.

In some embodiments, the material of the light-emitting layer further includes a stabilizing material. In the thickness direction of the light-emitting layer, a mass concentration of the stabilizing material in the light-emitting layer is substantially the same.

In some embodiments, the light-emitting device includes a plurality of light-emitting units disposed between the first electrode and the second electrode, and at least one light-emitting unit includes the light-emitting layer. The light-emitting device further includes a charge generation layer disposed between two adjacent light-emitting units, and the charge generation layer is used to connect the two adjacent light-emitting units.

In yet another aspect, a display substrate is provided. The display substrate includes the light-emitting device as described in any of the above embodiments, and a back plate electrically connected to the light-emitting device.

In yet another aspect, a display apparatus is provided. The display apparatus includes the display substrate as described in the above embodiment, and a driver chip electrically connected to the display substrate.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product to which the embodiments of the present disclosure relate.

FIG. 1A is a schematic diagram of a display apparatus, in accordance with some embodiments of the present disclosure;

FIG. 1B is a schematic diagram of another display apparatus, in accordance with some embodiments of the present disclosure;

FIG. 2 is a structural diagram of a display substrate, in accordance with some embodiments of the present disclosure;

FIG. 3 is a structural diagram of a light-emitting device, in accordance with some embodiments of the present disclosure;

FIG. 4 is a structural diagram of another light-emitting device, in accordance with some embodiments of the present disclosure;

FIG. 5 is a structural diagram of another light-emitting device, in accordance with some embodiments of the present disclosure;

FIG. 6 is a structural diagram of another light-emitting device, in accordance with some embodiments of the present disclosure;

FIG. 7 is a structural diagram of another light-emitting device, in accordance with some embodiments of the present disclosure;

FIG. 8 is a structural diagram of another light-emitting device, in accordance with some embodiments of the present disclosure;

FIG. 9 is a diagram showing a process of manufacturing a light-emitting layer of a light-emitting device, in accordance with some embodiments of the present disclosure;

FIG. 10 is a structural diagram of another light-emitting device, in accordance with some embodiments of the present disclosure;

FIG. 11 is a structural diagram of another light-emitting device, in accordance with some embodiments of the present disclosure;

FIG. 12 is a diagram showing an emission spectrum of a sensitizing material of a light-emitting layer, an absorption spectrum of a guest material, and an absorption spectrum of a stabilizing material, in accordance with some embodiments of the present disclosure; and

FIG. 13 is a diagram showing emission spectrums of two light-emitting devices, in accordance with some embodiments of the present disclosure.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “perpendicular” includes absolute perpendicularity and approximate perpendicularity, and an acceptable range of deviation of the approximate perpendicularity may also be a deviation within 5°, and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plane views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in a device, and are not intended to limit the scope of the exemplary embodiments.

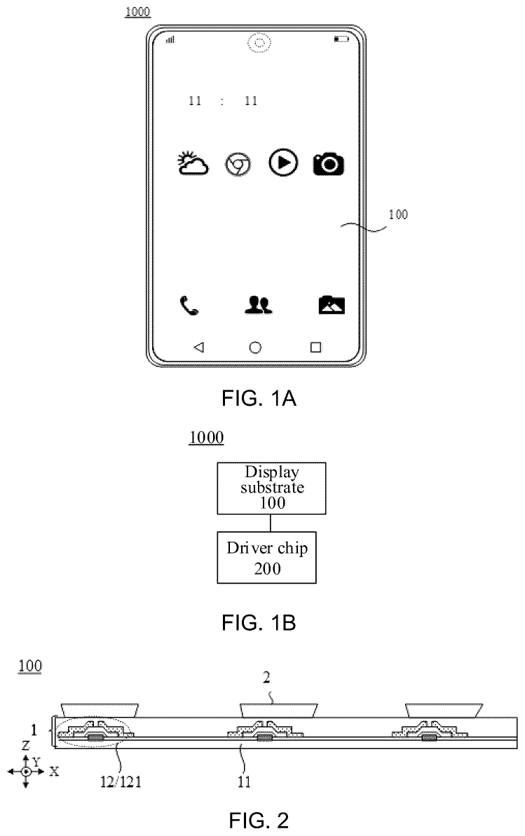

As shown in FIG. 1A, some embodiments of the present disclosure provide a display apparatus 1000. The display apparatus 1000 may be any display apparatus that displays images whether in motion (such as a video) or fixed (such as a still image), and regardless of text or image. More specifically, it is expected that the display apparatus in the embodiments may be implemented in or associated with a variety of electronic devices. The variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

In some examples, as shown in FIG. 1B, the display apparatus 1000 includes a frame, and a display substrate 100, a circuit board and a driver chip 200 (integrated circuit (IC)) and other electronic components that are provided in the frame.

The display substrate 100 may be, for example, an organic light-emitting diode (OLED) display substrate, a quantum dot light-emitting diode (QLED) display substrate, a micro light-emitting diode (micro LED) display substrate or a mini light-emitting diode (mini LED) display substrate, which is not specifically limited in the present disclosure.

Some embodiments of the present disclosure will be exemplarily described below by considering an example in which the display substrate 100 is the OLED display substrate.

In some examples, as shown in FIG. 2, the display substrate 100 includes a back plate 1.

It can be understood that a symbol X in FIG. 2 represents a first direction, a symbol Y represents a second direction, and a symbol Z represents a third direction. The first direction X and the second direction Y are parallel to a plane where a substrate 11 is located, and the third direction Z is a direction perpendicular to the plane where the substrate 11 is located, and may also be a thickness direction of the substrate 11.

In some examples, the back plate 1 includes the substrate 11 and a plurality of pixel driving circuits 12 disposed on the substrate 11.

The type of the substrate 11 may vary, and may be selected depending on actual needs.

For example, the substrate 11 is a rigid substrate. A material of the rigid substrate may include, for example, glass, quartz, plastic, sapphire, or silicon wafer.

For example, the substrate 11 is a flexible substrate. A material of the flexible substrate may include, for example, polyethylene terephthalate (PET), polyethylene naphthalate (PEN) or polyimide (PI).

In some examples, the plurality of pixel driving circuits 21 are arranged, for example, in an array.

The structure of the pixel driving circuit 12 varies, and may be selected depending on actual needs. For example, the structure of the pixel driving circuit 12 includes a “3T1C” structure, a “4T1C” structure, a “6T1C” structure, a “7T1C” structure, a “6T2C” structure, a “7T2C” structure or a “8T2C” structure. Here, “T” represents a transistor, the number in front of “T” represents the number of transistor(s), “C” represents a storage capacitor, and the number in front of “C” represents the number of storage capacitor(s).

For example, FIG. 2 only shows a transistor 121 in a pixel driving circuit 12.

In some embodiments, as shown in FIG. 2, the display substrate 100 further includes a light-emitting device layer.

In some examples, as shown in FIG. 2, the light-emitting device layer includes a plurality of light-emitting devices 2, and the plurality of light-emitting devices 2 are arranged, for example, in an array. The light-emitting device is, for example, an OLED light-emitting device.

For example, the type of the light-emitting device is a bottom-emission structure or a top-emission structure.

It can be understood that for a light-emitting device with a top-emission structure, light emitted by a light-emitting layer exits from a cathode. For a light-emitting device with a bottom-emission structure, light emitted by a light-emitting layer exits from an anode.

The back plate 1 is electrically connected to the light-emitting device 2 by a pixel driving circuit 12. The electrical connection relationship between the pixel driving circuits 12 and the light-emitting device 2 varies and may be selected specifically depending on actual needs, which is not limited in the present disclosure.

For example, the pixel driving circuits 12 and the light-emitting devices 2 are electrically connected in one-to-one correspondence. As another example, a pixel driving circuit 12 is electrically connected to multiple light-emitting devices 2. As another example, multiple pixel driving circuits 12 are electrically connected to a light-emitting device 2.

The structure of the display substrate 100 will be exemplarily described below by considering an example in which the pixel driving circuits 12 and the light-emitting devices 2 are electrically connected in one-to-one correspondence.

It can be understood that the pixel driving circuit 12 can generate a driving signal and transmit the driving signal to a corresponding light-emitting device 2 to control an emission state of the light-emitting device 2. The emission state includes, for example, whether the light-emitting device 2 emits light, or the luminous brightness of the light-emitting device 2. The plurality of pixel driving circuits 12 jointly control the emission states of the plurality of light-emitting devices 2, thereby enabling the display substrate 100 to achieve display of images.

Here, each pixel driving circuit 12 and the light-emitting device 2 connected thereto may be referred to as a sub-pixel.

In an implementation, a material system of the light-emitting layer in the light-emitting device generally includes a sensitizer material such as a phosphorescent material or a thermal active delay fluorescent (TADF) material, and luminescence is achieved using sensitized fluorescence technology, so that light emitted by the light-emitting device has relatively high color purity. However, the light-emitting device formed by the material system of the above light-emitting layer has a relatively low luminous efficiency.

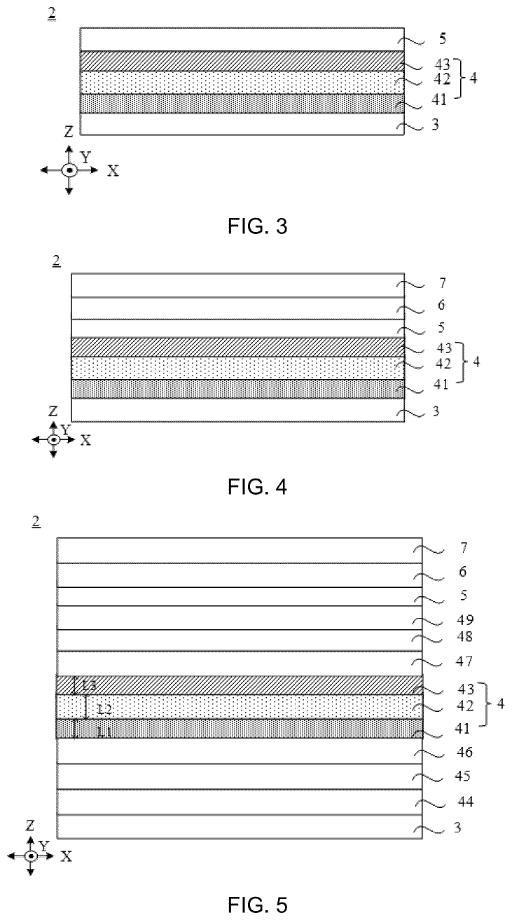

In light of this, embodiments of the present disclosure provide a light-emitting device. As shown in FIG. 3, the light-emitting device 2 includes a first electrode 3, a light-emitting layer 4 and a second electrode 5 that are stacked sequentially.

For example, the first electrode 3 is one of an anode and a cathode, and the second electrode 5 is the other of the anode and the cathode. The description is made below by considering an example where the first electrode 3 is an anode and the second electrode 5 is a cathode.

For example, each light-emitting device 2 is electrically connected to a corresponding pixel driving circuit through the anode to receive a driving signal provided by the pixel driving circuit. The cathode is used to receive a common voltage signal. Holes injected from a side of the anode reach the light-emitting layer, electrons injected from a side of the cathode reach the light-emitting layer, and the holes and the electrons that reach the light-emitting layer recombine in the light-emitting layer to form excitons. The excitons radiate and transition to emit light, producing a luminescence phenomenon, namely electroluminescence.

A material of the light-emitting layer may include a host material, a guest material, a sensitizing material, and the like. The host material is used to evenly disperse the guest material and the sensitizing material to avoid quenching caused by aggregating of the guest material and the sensitizing material. The sensitizing material may produce excitons, and the excitons and a luminous center formed by molecules of the guest material can transfer energy to emit light.

In some embodiments, the light-emitting layer 4 includes a first light-emitting layer 41, a second light-emitting layer 42 and a third light-emitting layer 43 which are stacked, and at least the second light-emitting layer 42 includes a sensitizing material.

It can be understood that the first light-emitting layer 41 may be made of one or more materials, the second light-emitting layer 42 may also be made of one or more materials, and the third light-emitting layer 43 may also be made of one or more materials. Selection may be made depending on actual needs, and is not limited in the present disclosure.

In some examples, a mass concentration X2 of the sensitizing material in a material of the second light-emitting layer 42 and a mass concentration X1 of the sensitizing material in a material of the first light-emitting layer 41 satisfy: X2 being greater than or equal to X1 (X2≥X1) and X1 being greater than or equal to 0 (X1≥0); and the mass concentration X2 of the sensitizing material in the material of the second light-emitting layer 42 and a mass concentration X3 of the sensitizing material in a material of the third light-emitting layer 43 satisfy: X2 being greater than or equal to X3 (X2≥X3) and X3 being greater than or equal to 0 (X3≥0).

For example, the materials of the first light-emitting layer 41, the second light-emitting layer 42 and the third light-emitting layer 43 all include sensitizing materials, and the sensitizing material in the second light-emitting layer 42 has the largest mass concentration.

As another example, the material of the first light-emitting layer 41 does not include a sensitizing material, the material of the third light-emitting layer 43 does not include a sensitizing material, and only the material of the second light-emitting layer 42 includes a sensitizing material. That is, X1 is equal to 0 (X1=0), X3 is equal to 0 (X3=0), and X2 is greater than 0 (X2>0).

For example, the mass concentration of the sensitizing material in the first light-emitting layer 41 and the mass concentration of the sensitizing material in the third light-emitting layer 43 may be equal or unequal.

It can be understood that at least the second light-emitting layer 42 includes the sensitizing material. Therefore, in a case where the mass concentration X1 of the sensitizing material in the first light-emitting layer 41 is 0, and the mass concentration X3 of the sensitizing material in the third light-emitting layer 43 is 0, the mass concentration X2 of the sensitizing material in the second light-emitting layer 42 is greater than X3 and greater than X1 (X2>X3 and X2>X1). That is, X1, X2 and X3 as above cannot all be 0.

The material of the second light-emitting layer 42 may include a host material, a guest material and a sensitizing material, and the three materials constitute a ternary light-emitting layer system. The sensitizing material may produce a variety of excitons, and the variety of excitons include excitons at a singlet energy level and excitons at a triplet energy level. Both singlet and triplet excitons may be used for energy transfer. The above setting may balance carrier transport. Moreover, the rather low concentrations of sensitizing materials in the first light-emitting layer and the third light-emitting layer are beneficial to suppressing quenching and enhancing energy transfer, and are beneficial to improving an overall efficiency of the device. The sensitizing material in the second light-emitting layer 42 has a relatively large mass concentration which is greater than the mass concentration of the sensitizing material in the first light-emitting layer 41 and the mass concentration of the sensitizing material in the third light-emitting layer 43. Therefore, there are more excitons used for energy transfer in the sensitizing material in the second light-emitting layer 42, so that the excitons and the guest material in the second light-emitting layer 42 perform more energy transfer, and thus the luminous center of the light-emitting device is substantially located in the second light-emitting layer 42, thereby improving the luminescence stability of the light-emitting device.

For example, in a case where the materials of the first light-emitting layer 41, the second light-emitting layer 42 and the third light-emitting layer 43 all include sensitizing materials, the sensitizing material included in the first light-emitting layer 41 is a first sensitizing material, the sensitizing material included in the second light-emitting layer 42 is a second sensitizing material, and the sensitizing material included in the third light-emitting layer 43 is a third sensitizing material. The first sensitizing material, the second sensitizing material and the third sensitizing material may be the same or different.

For example, the sensitizing material may be a material having phosphorescent properties, such as an Iridium (Ir) or Platinum (Pt) coordination compound material. The sensitizing material may alternatively be a material having thermal active delay fluorescent (TADF) properties, such as a polycarbazole material 4CzPIN (3,4,5,6-tetrakis(carbazol-9-yl)-1,2-dicyanobenzene).

In some examples, a material of the anode in the light-emitting device may be an electrode material with a high work function.

For example, in a case where the light-emitting device 2 has a bottom-emission structure, the material of the anode may be a transparent oxide, such as indium tin oxide (ITO) or indium zinc oxide (IZO). Here, a thickness of the anode may be in a range of 80 nm to 200 nm, inclusive.

For example, in a case where the light-emitting device 2 has a top-emission structure, the anode may be a reflective composite electrode. On this basis, the material of the anode may be a composite material, for example, a composite material composed of a metal material and a transparent oxide material, such as Argentum (Ag, silver)/ITO, aluminum (AI)/ITO, Ag/IZO or Al/IZO. In the above anode materials, a thickness of the metal material may be in a range of 10 nm to 100 nm, inclusive, and a thickness of the transparent oxide material may be in a range of 5 nm to 20 nm, inclusive.

For example, a material of the cathode may be an electrode material with a low work function.

For example, the material of the cathode may be a metal material, such as Al, Ag or Magnesium (Mg). The material of the cathode may alternatively be an alloy material.

For example, in a case where the light-emitting device 2 has a bottom-emission structure, a thickness of the cathode may be greater than or equal to 80 nm, so as to ensure a good reflectivity of the cathode, thereby improving the luminous efficiency of the light-emitting device 2. For example, the cathode has a reflectivity greater than or equal to 85% for light with an incident wavelength of about 550 nm.

For example, in a case where the light-emitting device 2 has a top-emission structure, the thickness of the cathode may be in a range of 10 nm to 20 nm, inclusive, so as to ensure a high transmittance of the cathode, so that the light-emitting device 2 has a high luminous efficiency. For example, the cathode has a transmittance greater than or equal to 45% for light with an incident wavelength of about 550 nm.

In some examples, as shown in FIG. 4, the light-emitting device 2 further includes an optical capping layer 6 (CPL) located on a side of the cathode away from the anode. The optical capping layer may increase a light extraction amount of the light-emitting device 2.

For example, a material of the optical capping layer 6 may be a small molecule material with a high refractive index. The optical capping layer 6 may be formed by evaporation.

For example, a thickness of the optical capping layer 6 is in a range of 50 nm to 100 nm, inclusive. For light with a wavelength of about 550 nm, the optical capping layer 6 has a refractive index greater than or equal to 1.8.

In some examples, as shown in FIG. 4, the light-emitting device 2 further includes an encapsulation structure 7. The encapsulation structure 7 is located on a side of the optical capping layer 6 away from the anode. The encapsulation structure 7 may isolate external moisture and oxygen, and avoid affecting light emission caused by erosion of the light-emitting layer 4 by moisture and oxygen, thereby increasing the luminescence life of the light-emitting device 2.

For example, the light-emitting device 2 may be encapsulated by thin film encapsulation or ultra violet (UV) sealant encapsulation.

In some examples, as shown in FIG. 5, the light-emitting device 2 further includes a hole injection layer 44 (HIL), a hole transport layer 45 (HTL) and an electron blocking layer 46 (EBL) that are located between the anode and the first light-emitting layer 41 and sequentially stacked on the anode.

For example, the hole injection layer 44 is used to reduce a hole injection barrier to improve the hole injection efficiency. The hole injection layer 44 may be a single-layer film made of a material such as hexaazatriphenylenehexacarbonitrile (HATCN), copper phthalocyanine (CuPc) or manganese (VI) oxide (MnO₃). The hole injection layer 44 may alternatively be formed by doping the hole transport material. For example, the dopant may be a p-type dopant, and a material of the p-type dopant may be an oxide-based inorganic material or a radialene-based organic material. In some examples, the hole injection layer 44 may be formed by multi-source co-evaporation.

For example, a thickness of the hole injection layer 44 is in a range of 1 nm to 30 nm, inclusive. The thickness of the hole injection layer 44 may be 1 nm, 10 nm, 12 nm, 15 nm or 30 nm.

For example, hole injection layers 44 of different light-emitting devices 2 in the light-emitting substrate are connected to form an integrated structure. Therefore, the manufacturing process of the light-emitting substrate may be simplified.

For example, the hole transport layer 45 is used to transport holes. A material of the hole transport layer 45 may include a carbazole or its derivative material with high hole mobility, so that the hole mobility may be high. A thickness of the hole transport layer 45 is in a range of 1 nm to 200 nm, inclusive. For example, the thickness of the hole transport layer 45 is 1 nm, 20 nm, 52 nm, 125 nm or 200 nm.

For example, in a case where the light-emitting device 2 emits green light or red light, the hole transport layer 45 in the light-emitting device 2 may be composed of a first hole transport sub-layer and a second hole transport sub-layer stacked in sequence. An absolute value of a highest occupied molecular orbital (HOMO) of the second hole transport sub-layer is greater than an absolute value of a HOMO of the first hole transport sub-layer, and thus a hole transport barrier may be reduced and a hole transport amount may increase, thereby being beneficial to improving the luminous efficiency of the light-emitting device 2.

For example, the electron blocking layer 46 may transfer holes to the light-emitting layer and may further block electrons and excitons.

For example, a thickness of the electron blocking layer 46 is in a range of 1 nm to 90 nm, inclusive.

For example, the electron blocking layer 46 may be formed by evaporation.

In some examples, a triplet state of the electron blocking layer 46 is greater than a triplet state of the first sensitizing material.

For example, a difference between the triplet state of the electron blocking layer 46 and the triplet state of the first sensitizing material is greater than 0.2 eV.

The above setting is conducive to transport of holes from the electron blocking layer 46 to the first light-emitting layer 41, so that a lot of holes and electrons are combined to form excitons to emit light, thereby improving the luminous efficiency of the light-emitting device 2.

In some examples, as shown in FIG. 5, the light-emitting device 2 further includes a hole blocking layer 47 (HBL), an electron transport layer 48 (ETL) and an electron injection layer 49 (EIL) that are sequentially stacked on the light-emitting layer (EML).

For example, the hole blocking layer 47 is used to transport electrons to the light-emitting layer 4 and block holes and excitons. A thickness of the hole blocking layer 47 is in a range of 5 nm to 30 nm, inclusive.

In some examples, a triplet state of the hole blocking layer 47 is greater than a triplet state of the third sensitizing material.

For example, a difference between the triplet state of the hole blocking layer 47 and the triplet state of the third sensitizing material is greater than or equal to 0.2 eV.

This facilitates transport of electrons from the hole blocking layer 47 to the third light-emitting layer 43, so that a lot of electrons and holes are combined to form excitons to emit light, thereby improving the luminous efficiency of the light-emitting device 2.

For example, the electron transport layer 48 is used to transport electrons. A material of the electron transport layer 48 may be a material having good electron transport properties. The electron transport layer 48 may be formed by evaporation.

For example, the material of the electron transport layer 48 may be composed of a material with electron transport properties doped with LiQ3 (8-Hydroxyquinolinolato-lithium), Li (Lithium), Ca (Calcium) or the like in a certain proportion. The above material with the electron transport properties may include triazine and derivatives thereof, pyridine materials and the like.

For example, a thickness of the electron transport layer 48 is in a range of 10 nm to 70 nm, inclusive.

For example, the electron injection layer 49 is used to reduce an electron injection barrier to improve the electron injection efficiency, thereby improving the light extraction efficiency of the light-emitting device 2.

For example, a material of the electron injection layer 49 may be a metal with a low work function such as Li, Ca or Ytterbium (Yb), or may be a metal salt such as lithium fluoride (LiF) or LiQ3. In some examples, the electron injection layer 49 may be formed by evaporation. For example, a thickness of the electron injection layer 49 is in a range of 0.5 nm to 2 nm, inclusive.

In some examples, a material of the light-emitting layer 4 includes a host material.

For example, the first light-emitting layer 41, the second light-emitting layer 42 and the third light-emitting layer 43 each include the host material.

For example, the host material may be a material having a single component, such as a P-type host material.

Of course, the host material may be a composite material having multiple components, such as a mixture of a P-type host material and an N-type host material, and the mixture is a mixture material having exciplex properties.

A host material included in the first light-emitting layer 41 is a first host material, a host material included in the second light-emitting layer 42 is a second host material, and a host material included in the third light-emitting layer 43 is a third host material. The first host material, the second host material and the third host material may be the same or different.

For example, in a case where the host material of the first light-emitting layer 41 includes only one material, a hole mobility of the material is greater than an electron mobility thereof. For example, a ratio of the hole mobility of the material to the electron mobility thereof is greater than or equal to 10. Therefore, a rate of injecting holes into the anode may increase, which is beneficial to improving the luminous efficiency of the light-emitting device 2.

For example, in a case where the host material of the third light-emitting layer 43 includes only one material, a hole mobility of the material is less than an electron mobility thereof. For example, a ratio of the electron mobility of the material to the hole mobility thereof is greater than or equal to 10. Therefore, a rate of injecting electrons into the cathode may increase, which is beneficial to improving the luminous efficiency of the light-emitting device 2.

In some examples, the mass concentration X2 of the sensitizing material in the material of the second light-emitting layer 42 satisfies: X2 being greater than or equal to 20% and less than or equal to 70% (20%≤X2≤70%). For example, the mass concentration X2 of the sensitizing material in the material of the second light-emitting layer 42 is 20%, 30%, 40%, 50%, 60% or 70%.

Therefore, the mass concentration X2 of the sensitizing material in the material of the second light-emitting layer 42 is set to be in a range of 20% to 70%, inclusive, and the relatively high mass concentration X2 may make the sensitizing material produce more excitons and more energy transfer with the luminous center of the guest material, thereby improving the luminous efficiency of the light-emitting device 2.

In some embodiments, the mass concentration X2 of the sensitizing material in the material of the second light-emitting layer 42 and the mass concentration X1 of the sensitizing material in the material of the first light-emitting layer 41 further satisfy:

$$0 \leq ( X 2 - X 1 ) \leq 15 \% .$$

For example, in a case where the mass concentration X2 of the sensitizing material in the material of the second light-emitting layer 42 is 45%, the mass concentration X1 of the sensitizing material in the material of the first light-emitting layer 41 is 30%, 35%, 40%, 42% or 45%.

With the above setting method, the mass concentration X2 of the sensitizing material in the material of the second light-emitting layer 42 is set to be the same as the mass concentration X1 of the sensitizing material in the material of the first light-emitting layer 41. During manufacturing the light-emitting layer, it is convenient to designing the mass concentrations of the sensitizing materials in the first light-emitting layer 41 and the second light-emitting layer 42, which is beneficial to simplify the manufacturing process of the light-emitting layer. The mass concentration X2 of the second sensitizing material in the material of the second light-emitting layer 42 and the mass concentration X1 of the first sensitizing material in the material of the first light-emitting layer 41 are set to satisfy X2>X1, and a difference therebetween is less than 15%. Thus, the carrier transport may be balanced, so that the luminous center of the light-emitting layer is concentrated in the second light-emitting layer 42, which is beneficial to optimizing the luminous efficiency of the light-emitting device 2.

In some embodiments, the mass concentration X2 of the sensitizing material in the material of the second light-emitting layer 42 and the mass concentration X3 of the sensitizing material in the material of the third light-emitting layer 43 further satisfy:

$$0 \leq ( X 2 - X 1 ) \leq 15 \% .$$

For example, the mass concentration X2 of the sensitizing material in the material of the second light-emitting layer 42 may be equal to the mass concentration X3 of the sensitizing material in the material of the third light-emitting layer 43. A difference between the mass concentration X2 of the sensitizing material in the material of the second light-emitting layer 42 and the mass concentration X3 of the sensitizing material in the material of the third light-emitting layer 43 may be 15%, 12%, 10%, 7% or 5%.

With the above setting method, the luminous center of the light-emitting device 2 is located in the second light-emitting layer 42, which is beneficial to improving the luminous efficiency of the light-emitting device 2.

In some examples, the mass concentration X1 of the sensitizing material in the first light-emitting layer 41 satisfies: X1 being greater than or equal to 3% and less than or equal to 50% (3%≤X1≤50%).

For example, the mass concentration X1 of the sensitizing material in the first light-emitting layer 41 is 3%, 13%, 25%, 37% or 50%.

For example, in a case where the mass concentration X2 of the sensitizing material in the material of the second light-emitting layer 42 is 50%, the mass concentration X1 of the sensitizing material in the first light-emitting layer 41 is 50% or 20%.

With the above setting method, since the mass concentration of the sensitizing material in the first light-emitting layer is relatively low, the mass concentration of the first host material in the first light-emitting layer 41 may be relatively large, so that the first sensitizing material are dispersed well, and the probability of exciton quenching may be reduced, thereby improving the luminous efficiency and luminescence stability of the light-emitting device 2. Moreover, since the hole transport rate of the first host material is relatively high, it is beneficial for the first light-emitting layer 41 to transporting more holes to the second light-emitting layer 42, and beneficial to increasing the number of excitons formed by the combination of holes and electrons, thereby facilitating the improvement of the luminous efficiency of the light-emitting device 2.

In some other examples, the mass concentration X3 of the sensitizing material in the material of the third light-emitting layer 43 satisfies: X3 being greater than or equal to 3% and less than or equal to 50% (3%≤X3≤50%).

For example, the mass concentration X3 of the sensitizing material in the material of the third light-emitting layer 43 is 3%, 13%, 25%, 30% or 50%.

For example, the mass concentration X3 of the sensitizing material in the material of the third light-emitting layer 43 may be equal to or unequal to the mass concentration X1 of the sensitizing material in the material of the first light-emitting layer 41.

With the above setting method, since the mass concentration of the sensitizing material in the third light-emitting layer 43 is relatively low, the mass concentration of the third host material in the third light-emitting layer 43 may be relatively large, so that the probability of quenching of excitons in the third light-emitting layer 43 may be reduced, which is conducive to effective energy transfer of the excitons, thereby improving the overall luminous efficiency of the light-emitting device 2.

In some other examples, the mass concentration X1 of the sensitizing material in the first light-emitting layer 41 satisfies: 3%≤X1≤50%.

Moreover, the mass concentration X3 of the sensitizing material in the material of the third light-emitting layer 43 satisfies: 3%≤X3≤50%.

Therefore, it is conducive to increasing the number of excitons formed by the combination of holes and electrons, thereby helping to improve the luminous efficiency of the light-emitting device 2.

In some embodiments, in the first light-emitting layer 41, the second light-emitting layer 42 and the third light-emitting layer 43, at least the second light-emitting layer 42 includes a guest material.

For example, the guest material may be used to generate a luminous center.

In some examples, a mass concentration Y2 of the guest material in the material of the second light-emitting layer 42 and a mass concentration Y1 of the guest material in the material of the first light-emitting layer 41 satisfy: Y2 being greater than or equal to Y1 (Y2≥Y1) and Y1 being greater than or equal to 0 (Y1≥0); and the mass concentration Y2 of the guest material in the material of the second light-emitting layer 42 and a mass concentration Y3 of the guest material in the material of the third light-emitting layer 43 satisfy: Y2 being greater than or equal to Y3 (Y2≥Y3) and Y3 being greater than or equal to 0 (Y3≥0).

For example, the materials of the first light-emitting layer 41, the second light-emitting layer 42 and the third light-emitting layer 43 all include guest materials, and the guest material in the second light-emitting layer 42 has the largest mass concentration.

As another example, the material of the first light-emitting layer 41 does not include a guest material, the material of the third light-emitting layer 43 does not include a guest material, and only the material of the second light-emitting layer 42 includes a guest material. That is, Y1 is equal to 0 (Y1=0), Y3 is equal to 0 (Y3=0), and Y2 is greater than 0 (Y2>0).

It can be understood that at least the second light-emitting layer 42 includes the guest material. Therefore, in a case where the mass concentration Y1 of the guest material in the first light-emitting layer 41 is 0, and the mass concentration Y3 of the guest material in the third light-emitting layer 43 is 0, the mass concentration Y2 of the guest material in the second light-emitting layer 42 is greater than Y3 and greater than Y1 (Y2>Y3 and Y2>Y1). That is, Y1, Y2 and Y3 as above cannot all be 0.

The above setting method may make the mass concentration of the guest material in the second light-emitting layer 42 relatively large and greater than the mass concentration of the guest material in the first light-emitting layer 41 and the mass concentration of the guest material in the third light-emitting layer 43, so that the guest material in the second light-emitting layer 42 may generate more luminous centers, and more luminous centers of the light-emitting device are located in the second light-emitting layer 42. The excess exciton energy in the first light-emitting layer 41 and the third light-emitting layer 43 promotes the second light-emitting layer 42 to emit light through energy transfer, thereby improving the luminescence stability of the light-emitting device 2 and improving the luminous efficiency of the light-emitting device 2.

Of course, the mass concentration of the guest material in the first light-emitting layer 41, the mass concentration of the guest material in the second light-emitting layer 42 and the mass concentration of the guest material in the third light-emitting layer 43 may be equal.

For example, in a case where the materials of the first light-emitting layer 41, the second light-emitting layer 42 and the third light-emitting layer 43 all include guest materials, the guest material included in the first light-emitting layer 41 is a first guest material, the guest material included in the second light-emitting layer 42 is a second guest material, and the guest material included in the third light-emitting layer 43 is a third guest material. The first guest material, the second guest material and the third guest material may be the same or different.

The guest material may be a coumarin, anthracene, or boron-containing organic compound material.

In some embodiments, the mass concentration Y2 of the guest material in the material of the second light-emitting layer 42 satisfies: Y2 being greater than or equal to 0.1% and less than or equal to 5% (0.1%≤Y2≤5%).

For example, the mass concentration Y2 of the guest material in the material of the second light-emitting layer 42 is 0.1%, 1.0%, 2.5%, 3.6% or 5%.

The above setting method is beneficial to improving the luminous efficiency of the light-emitting device 2.

For example, the mass concentration Y1 of the guest material in the material of the first light-emitting layer 41 may also satisfy: Y1 being greater than or equal to 0.1% and less than or equal to 5% (0.1%≤Y1≤5%), and the mass concentration Y3 of the guest material in the material of the third light-emitting layer 43 may also satisfy: Y3 being greater than or equal to 0.1% and less than or equal to 5% (0.1%≤Y3≤5%).

In some embodiments, the second light-emitting layer 42 further includes a second stabilizing material.

For example, the second stabilizing material may consume excess excitons, inhibit quenching of excitons, and avoid an influence of quenching of excitons on the luminescence stability, thereby improving the luminescence stability of the light-emitting device 2 and increasing the luminescence life of the light-emitting device 2.

For example, the second stabilizing material may be a material having TADF properties or a material having phosphorescent properties.

In some embodiments, a mass concentration of the second stabilizing material in the material of the second light-emitting layer 42 is less than or equal to 5%.

For example, the mass concentration of the second stabilizing material in the material of the second light-emitting layer 42 is 5%, 4.5%, 3.7%, 2.5% or 1.5%.

The above setting method may avoid consuming excessive excitons due to a large mass concentration of the second stabilizing material in the material of the second light-emitting layer 42, thereby ensuring the luminous efficiency of the second light-emitting layer 42.

In some examples, a difference between a triplet state of at least one of the second host material, the second sensitizing material and the second guest material and a triplet state of the second stabilizing material is less than or equal to 0.3 eV. For example, it is 0.30 eV, 0.27 eV, 0.24 eV, 0.19 eV or 0.1 eV.

The above setting method may make the triplet state of the second stabilizing material close to the triplet state of at least one of the second host material, the second sensitizing material and the second guest material, which is beneficial for the second stabilizing material to consuming excess excitons, thereby ensuring the luminescence stability of the second light-emitting layer 42 of the light-emitting device 2, and being beneficial to improving the luminescence life of the light-emitting device 2.

In some other examples, an overlapping area between a normalized emission spectrum of at least one of the second host material, the second sensitizing material and the second guest material and a normalized absorption spectrum of the second stabilizing material is greater than or equal to 30% of an integrated area of the normalized absorption spectrum of the second stabilizing material.

For example, an overlapping area between a normalized emission spectrum of at least one of the second host material, the second sensitizing material and the second guest material and a normalized absorption spectrum of the second stabilizing material is 30%, 32%, 37%, 42% or 45% of an integrated area of the normalized absorption spectrum of the second stabilizing material.

With the above setting method, excitons generated by at least one of the second host material, the second sensitizing material and the second guest material may be consumed well by the second stabilizing material, thereby ensuring the luminescence stability of the second light-emitting layer 42 of the light-emitting device 2.

In some other examples, a difference between a triplet state of at least one of the second host material, the second sensitizing material and the second guest material and a triplet state of the second stabilizing material is less than or equal to 0.3 eV, and an overlapping area between a normalized emission spectrum of at least one of the second host material, the second sensitizing material and the second guest material and a normalized absorption spectrum of the second stabilizing material is greater than or equal to 30% of an integrated area of the normalized absorption spectrum of the second stabilizing material.

Therefore, the luminescence stability of the second light-emitting layer 42 may be ensured, thereby improving the luminescence life of the light-emitting device 2.

In some embodiments, a wavelength of a photoemission spectrum peak of the second host material is less than a wavelength of a photoemission spectrum peak of the second sensitizing material, the wavelength of the photoemission spectrum peak of the second sensitizing material is less than a wavelength of a photoemission spectrum peak of the second stabilizing material; and a wavelength of a photoemission spectrum peak of the second guest material is less than the wavelength of the photoemission spectrum peak of the second stabilizing material.

The above setting method may make an energy of excitons of the second host material greater than an energy of excitons of the second sensitizing material, so that the energy of the excitons of the second host material can be transferred to the excitons of the second sensitizing material, thereby being beneficial for the second sensitizing material to transferring energy to the second guest material, and beneficial to improving the luminescence of the second light-emitting layer 42. Moreover, the energy of the excitons of the second sensitizing material may also be made greater than an energy of excitons of the second stabilizing material, so that the energy of the excitons of the second sensitizing material can be transferred to the second stabilizing material, and thus the second stabilizing material may consume part of excitons or energy, thereby being beneficial to improving the luminescence stability of the light-emitting device 2. In addition, an energy of excitons of the second guest material may also be made greater than the energy of the excitons of the second stabilizing material, so that the energy of the excitons of the second guest material can be transferred to the second stabilizing material, and thus the second stabilizing material may consume more excitons, thereby being beneficial to improving the luminescence stability of the light-emitting device 2 and extending the luminescence life of the light-emitting device 2.

In some embodiments, the material of the first light-emitting layer 41 further includes a first stabilizing material.

In some embodiments, the material of the third light-emitting layer 43 further includes a third stabilizing material.

For example, the first stabilizing material and the third stabilizing material may have the same function as the second stabilizing material. The first stabilizing material, the second stabilizing material and the third stabilizing material may be the same or different.

For example, the first stabilizing material may be a material having fluorescent properties or a material having phosphorescent properties.

In some examples, a difference between an absolute value of the highest occupied molecular orbital energy level of the electron blocking layer 46 and an absolute value of the largest highest occupied molecular orbital energy level of the first host material, the first guest material, the first sensitizing material and the first stabilizing material of the material of the first light-emitting layer 41 is greater than or equal to 0.3 eV.

Therefore, this is beneficial to improving the luminous efficiency of the light-emitting device 2.

For example, the material composition of the first light-emitting layer 41, the material composition of the second light-emitting layer 42 and the material composition of the third light-emitting layer 43 may be the same or different, and may be selected depending on actual conditions, which is not limited in the present disclosure.

For example, the material of the first light-emitting layer 41 may only include a first host material, a first guest material and a first sensitizing material; the material of the second light-emitting layer 42 may only include a second host material, a second guest material and a second sensitizing material; and the material of the third light-emitting layer 43 may only include a third host material, a third guest material and a third sensitizing material.

As another example, the material of the first light-emitting layer 41 may only include a first host material and a first guest material; the material of the second light-emitting layer 42 may only include a second host material, a second guest material and a second sensitizing material; and the material of the third light-emitting layer 43 may only include a third host material and a third guest material.

As another example, the material of the first light-emitting layer 41 may only include a first host material and a first sensitizing material; the material of the second light-emitting layer 42 may only include a second host material, a second guest material and a second sensitizing material; and the material of the third light-emitting layer 43 may only include a third host material and a third guest material.

As another example, the material of the first light-emitting layer 41 may only include a first host material, a first guest material and a first sensitizing material; the material of the second light-emitting layer 42 may only include a second host material, a second guest material, a second sensitizing material and a second sensitizing material; and the material of the third light-emitting layer 43 may only include a third host material, a third guest material and a third sensitizing material.

As another example, the material of the first light-emitting layer 41 may only include a first host material; the material of the second light-emitting layer 42 may only include a second host material, a second guest material and a second sensitizing material; and the material of the third light-emitting layer 43 may only include a third host material. Here, the third host material of the third light-emitting layer 43 has electron transport properties, an electron transport rate of the third host material is much greater than a hole transport rate thereof, and a ratio of the electron transport rate of the third host material to the hole transport rate thereof is greater than or equal to 10.

In some examples, in a case where the second light-emitting layer includes a second host material, a second guest material, a second sensitizing material and a second stabilizing material, a difference between a triplet state of at least one of the second host material, the second guest material and the second sensitizing material and a triplet state of the second stabilizing material is less than or equal to 0.3 eV.

For example, a difference between a triplet state of at least one of the second host material and the second sensitizing material and a triplet state of the second stabilizing material is 0.3 eV, 0.28 eV, 0.25 eV, 0.20 eV or 0.18 eV.

The above setting method makes the triplet state of the second stabilizing material close to the triplet state of at least one of the second host material, the second guest material and the second sensitizing material, which is beneficial for the second stabilizing material to consuming excess excitons, thereby ensuring the luminescence stability of the second light-emitting layer 42 of the light-emitting device 2.

In some other examples, an overlapping area between a normalized emission spectrum of at least one of the second host material, the second guest material and the second sensitizing material and a normalized absorption spectrum of the second stabilizing material is greater than or equal to 30% of an integrated area of the normalized absorption spectrum of the second stabilizing material.

For example, an overlapping area between a normalized emission spectrum of at least one of the second host material and the second sensitizing material and a normalized absorption spectrum of the second stabilizing material is 30%, 35%, 37%, 40% or 42% of an integrated area of the normalized absorption spectrum of the second stabilizing material.

With the above setting method, excitons generated by at least one of the second host material, the second sensitizing material and the second guest material may be consumed well by the second stabilizing material, thereby ensuring the luminescence stability of the second light-emitting layer 42 of the light-emitting device 2.

In yet other examples, a difference between a triplet state of at least one of the second host material, the second guest material and the second sensitizing material and a triplet state of the second stabilizing material is less than or equal to 0.3 eV. Moreover, an overlapping area between a normalized emission spectrum of at least one of the second host material, the second guest material and the second sensitizing material and a normalized absorption spectrum of the second stabilizing material is greater than or equal to 30% of an integrated area of the normalized absorption spectrum of the second stabilizing material.

Therefore, the luminescence stability of the second light-emitting layer 42 of the light-emitting device 2 may be ensured.

In some examples, in a case where the first light-emitting layer 41 includes a first host material, a first guest material, a first sensitizing material and a first stabilizing material, a difference between a triplet state of at least one of the first host material, the first guest material and the first sensitizing material and a triplet state of the first stabilizing material is less than or equal to 0.3 eV.

For example, a difference between a triplet state of at least one of the first host material, the first guest material and the first sensitizing material and a triplet state of the first stabilizing material is 0.3 eV, 0.28 eV, 0.25 eV, 0.20 eV or 0.18 eV.

The above setting method may make the triplet state of at least one of the first host material, the first guest material and the first sensitizing material close to the triplet state of the first stabilizing material, which is beneficial for the first stabilizing material to consuming excess excitons, thereby ensuring the luminescence stability of the first light-emitting layer 41 of the light-emitting device 2.

In some other examples, an overlapping area between a normalized emission spectrum of at least one of the first host material, the first guest material and the first sensitizing material and a normalized absorption spectrum of the first stabilizing material is greater than or equal to 30% of an integrated area of the normalized absorption spectrum of the first stabilizing material.

For example, an overlapping area between a normalized emission spectrum of at least one of the first host material, the first guest material and the first sensitizing material and a normalized absorption spectrum of the first stabilizing material is 30%, 35%, 37%, 40% or 42% of an integrated area of the normalized absorption spectrum of the first stabilizing material.

With the above setting method, excitons generated by at least one of the first host material, the first guest material and the first sensitizing material may be consumed well by the first stabilizing material, thereby ensuring the luminescence stability of the first light-emitting layer 41 of the light-emitting device 2.

In yet other examples, a difference between a triplet state of at least one of the first host material, the first guest material and the first sensitizing material and a triplet state of the first stabilizing material is less than or equal to 0.3 eV. Moreover, an overlapping area between a normalized emission spectrum of at least one of the first host material, the first guest material and the first sensitizing material and a normalized absorption spectrum of the first stabilizing material is greater than or equal to 30% of an integrated area of the normalized absorption spectrum of the first stabilizing material. Therefore, the luminescence stability of the first light-emitting layer 41 of the light-emitting device 2 may be ensured.

It can be understood that in a case where the third light-emitting layer includes a third host material, a third guest material, a third sensitizing material and a third stabilizing material, a difference between a triplet state of at least one of the third host material, the third guest material and the third sensitizing material and a triplet state of the third stabilizing material is less than or equal to 0.3 eV, and/or an overlapping area between a normalized emission spectrum of at least one of the third host material, the third guest material and the third sensitizing material and a normalized absorption spectrum of the third stabilizing material is greater than or equal to 30% of an integrated area of the normalized absorption spectrum of the third stabilizing material. Therefore, the luminescence stability of the third light-emitting layer 43 of the light-emitting device 2 may be ensured.

In some embodiments, an overlapping area between a normalized emission spectrum of the second sensitizing material and a normalized absorption spectrum of the second guest material is greater than or equal to 60% of an integrated area of the normalized absorption spectrum of the second guest material.

For example, an overlapping area between a normalized emission spectrum of the second sensitizing material and a normalized absorption spectrum of the second guest material is 60%, 63%, 65%, 68% or 70% of an integrated area of the normalized absorption spectrum of the second guest material.

With the above setting method, light emitted by the second sensitizing material may excite the second guest material to emit more light, which is beneficial for the second sensitizing material to transferring energy to the second guest material. As a result, the luminous efficiency of the second guest material may be improved, thereby facilitating improving the luminous efficiency of the second light-emitting layer 42.

In some examples, an overlapping area between a normalized emission spectrum of the third sensitizing material and a normalized absorption spectrum of the second guest material is greater than or equal to 60% of an integrated area of the normalized absorption spectrum of the second guest material.

For example, an overlapping area between a normalized emission spectrum of the third sensitizing material and a normalized absorption spectrum of the second guest material is 60%, 63%, 65%, 70% or 72% of an integrated area of the normalized absorption spectrum of the second guest material.

Therefore, more light emitted by the third sensitizing material may be absorbed by the second guest material and emit more light after being excited, thereby improving the luminous efficiency of the second guest material and the second light-emitting layer 42.

In some other examples, an overlapping area between a normalized emission spectrum of the first sensitizing material and a normalized absorption spectrum of the second guest material is greater than or equal to 60% of an integrated area of the normalized absorption spectrum of the second guest material.

For example, an overlapping area between a normalized emission spectrum of the first sensitizing material and a normalized absorption spectrum of the second guest material is 60%, 63%, 65%, 70% or 72% of an integrated area of the normalized absorption spectrum of the second guest material.

Therefore, more light emitted by the first sensitizing material may be absorbed by the second guest material and emit more light after being excited, thereby improving the luminous efficiency of the second guest material and the second light-emitting layer 42.

In some other examples, an overlapping area between a normalized emission spectrum of the third sensitizing material and a normalized absorption spectrum of the second guest material is greater than or equal to 60% of an integrated area of the normalized absorption spectrum of the second guest material, and an overlapping area between a normalized emission spectrum of the first sensitizing material and a normalized absorption spectrum of the second guest material is greater than or equal to 60% of an integrated area of the normalized absorption spectrum of the second guest material. Thus, the luminous efficiency of the second guest material and the second light-emitting layer 42 may be improved.

In some embodiments, in a case where the material of the first light-emitting layer 41 further includes a first sensitizing material, and the material of the third light-emitting layer 43 includes a third host material, a highest occupied molecular orbital energy level of the first host material is HOMO(A), a highest occupied molecular orbital energy level of the first sensitizing material is HOMO(B), a highest occupied molecular orbital energy level of the second host material is HOMO(E), a highest occupied molecular orbital energy level of the second sensitizing material is HOMO(F), a highest occupied molecular orbital energy level of the third host material is HOMO(J), and a highest occupied molecular orbital energy level of the third sensitizing material is HOMO(K), where HOMO(A), HOMO(B), HOMO(E), HOMO(F), HOMO(J) and HOMO(K) satisfy:

$$\vert HOMO ( A ) \vert \leq \vert HOMO ( B ) \vert , \vert HOMO ( E ) \leq \vert HOMO ( F ) \vert ,$$

$$\vert HOMO ( J ) \vert \leq \vert HOMO ( K ) \vert , \vert HOMO ( A ) \vert \leq \vert HOMO ( F ) \vert ,$$

$$\vert HOMO ( E ) \vert \leq \vert HOMO ( K ) \vert , \vert HOMO ( A ) - HOMO ( E ) \vert \leq 0.25 eV ,$$

$$\vert HOMO ( E ) - H O M O ( J ) \vert \leq 0.25 eV , \vert HOM O ( A ) - H O M O ( B ) \vert \leq 0.25 eV ,$$

$$\vert HOMO ( E ) - H O M O ( F ) \vert \leq 0.25 eV , \vert HOM O ( J ) - H O M O ( K ) \vert \leq 0.25 eV ,$$

$$\vert HOMO ( A ) - H O M O ( F ) \vert \leq 0.25 eV and$$

$$\vert HOMO ( E ) - H O M O ( K ) \vert \leq 0.25 eV .$$

For example, the function of the third host material is the same as the function of the first host material, and the third host material and the first host material may be the same or different.

$$For example , \vert HOMO ( A ) - HOMO ( E ) \vert < 0.25 eV ,$$

$$or \vert HOMO ( A ) - HOMO ( E ) \vert = 0.25 eV .$$

$$For example , \vert HOMO ( E ) - HOMO ( J ) \vert < 0.25 eV ,$$

$$or \vert HOMO ( E ) - HOMO ( J ) \vert = 0.25 eV .$$

Setting an absolute value of an energy level difference between HOMO(A) and HOMO(E) within the above range is beneficial to transport of holes from the first light-emitting layer 41 to the second light-emitting layer 42. Similarly, setting an absolute value of an energy level difference between HOMO(J) and HOMO(E) within the above range is beneficial to transport of holes from the second light-emitting layer 42 to the third light-emitting layer 43. Thus, the luminous efficiency of the light-emitting device 2 may be improved.

Setting an absolute value of HOMO(A) to be less than or equal to an absolute value of HOMO(B), and a difference between the two to be less than or equal to 0.25 eV may allow the first host material to transfer energy to the first sensitizing material, thereby facilitating improving the luminous efficiency of the first light-emitting layer 41. Similarly, setting |HOMO(E)|≤|HOMO(F)| and |HOMO(J)|≤|HOMO(K)| is beneficial to improving the luminous efficiencies of the second light-emitting layer 42 and the third light-emitting layer 43.

In some embodiments, a triplet state of the first host material is T1(A), a triplet state of the first sensitizing material is T1(B), a triplet state of the second host material is T1(E), a triplet state of the second sensitizing material is T1(F), a triplet state of the third host material is T1(J), and a triplet state of the third sensitizing material is T1(K), where T1(A), T1(B), T1(E), T1(F), T1(J) and T1(K) satisfy:

$$\vert T 1 ( A ) - T 1 ( E ) \vert \leq 0.15 eV , \vert T 1 ( E ) - T 1 ( J ) \vert \leq 0.15 eV ;$$

$$T 1 ( A ) \geq T 1 ( B ) , T 1 ( E ) \geq T 1 ( F ) and T 1 ( J ) \geq T 1 ( K ) .$$

The above setting method is beneficial to the energy transfer between the second host material and the first host material, and between the second host material and the third host material, and the energy transfer between the first host material and the first sensitizing material, between the second host material and the second sensitizing material, and between the third host material and the third sensitizing material, thereby facilitating improvement of the luminous efficiency of the light-emitting device 2.

In some embodiments, an electroluminescence amount of the second light-emitting layer 42 is greater than or equal to 50% of a total luminescence amount of the light-emitting device 2.

For example, an electroluminescence amount of the second light-emitting layer 42 is 50%, 55%, 60%, 70% or 75% of the total luminescence amount of the light-emitting device 2.

The above setting method may ensure that luminescence of recombination of excitons in the light-emitting device 2 is mainly concentrated in the second light-emitting layer 42, which is beneficial to improving the luminous efficiency of the light-emitting device 2.

In some embodiments, an overlapping area between a normalized emission spectrum of the second guest material and a normalized emission spectrum of the light-emitting device 2 is greater than or equal to 80% of an integrated area of the normalized emission spectrum of the second guest material.

For example, 80%, 82%, 85%, 89% or 91% of the integrated area of the normalized emission spectrum of the second guest material overlaps with the normalized emission spectrum of the light-emitting device 2.

The above setting method may ensure that a film layer of the light-emitting device 2 for emitting light is mainly concentrated in the second light-emitting layer 42, which is beneficial to improving the luminescence stability of the light-emitting device 2.

In some embodiments, as shown in FIG. 5, a thickness L1 of the first light-emitting layer 41, a thickness L2 of the second light-emitting layer 42, and a thickness L3 of the third light-emitting layer 43 satisfy: L2 being greater than L1, and L2 being greater than L3 (L2>L1 and L2>L3).

For example, the thickness L1 of the first light-emitting layer 41 and the thickness L2 of the second light-emitting layer 42 may be equal or unequal.

The above setting may allow light emitted by the light-emitting device 2 to have a relatively high color purity, which is beneficial to improving a display effect of the display panel.

In some examples, the thickness L1 of the first light-emitting layer 41, the thickness L2 of the second light-emitting layer 42, and the thickness L3 of the third light-emitting layer 43 satisfy: L2 being greater than or equal to a sum of L1 and L3 (L2≥L1+L3).

Thus, the thickness L2 of the second light-emitting layer 42 may be relatively large, which is beneficial to improving the color purity of the light emitted by the light-emitting device 2 and further improving the display effect of the display panel.

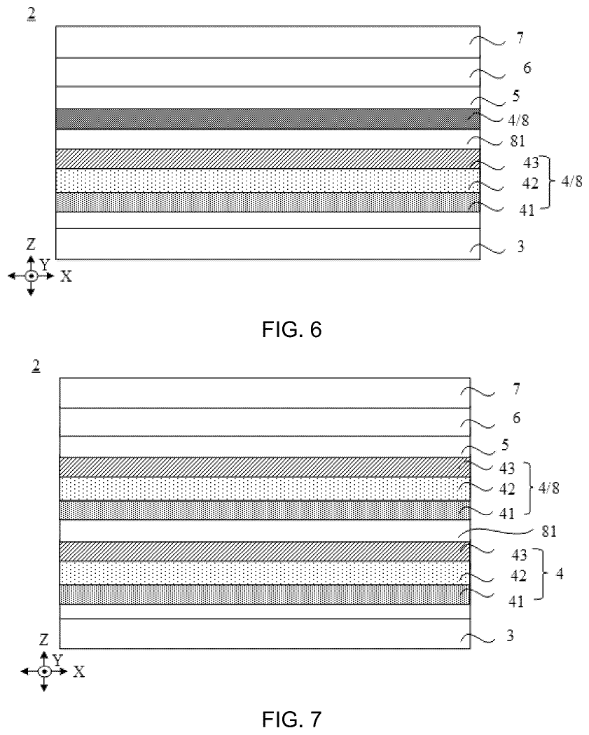

In some embodiments, as shown in FIGS. 6 and 7, the light-emitting device 2 includes a plurality of light-emitting unit 8 stacked between the first electrode 3 and the second electrode 5, and each light-emitting unit 8 includes the first light-emitting layer 41, the second light-emitting layer 42 and the third light-emitting layer 43.

The light-emitting device 2 further includes a charge generation layer 81 disposed between two adjacent light-emitting units 8, and the charge generation layer 81 is used to connect the two adjacent light-emitting units 8.

For example, the charge generation layer 81 includes an N-type charge generation layer (CGL) and a P-type CGL. The N-type CGL may be composed of an electron transport material doped with active metal(s) with low work function (such as Li, Ca, Yb). The P-type CGL may be composed of a hole transport material doped with a P-type dopant (such as molybdenum oxide).

For example, in a case where the light-emitting device 2 is a light-emitting device 2 with a top-emission structure, a light color and a light extraction efficiency of the light-emitting device 2 may be adjusted by controlling a thickness of the hole transport material in the P-type CGL.

It can be understood that in the above light-emitting device 2, a light-emitting layer 4 of a light-emitting unit 8 may absorb light emitted by a light-emitting layer of an adjacent light-emitting unit and be excited to emit light, thereby making the light-emitting device 2 have a high light extraction efficiency.

A series structure constituted by the plurality of light-emitting units makes the light-emitting device 2 a series light-emitting device 2.

The structures and material compositions of the first light-emitting layer 41, the second light-emitting layer 42 and the third light-emitting layer 43 in the light-emitting unit 8 may refer to the description of some of the above embodiments, and details are not repeated here.

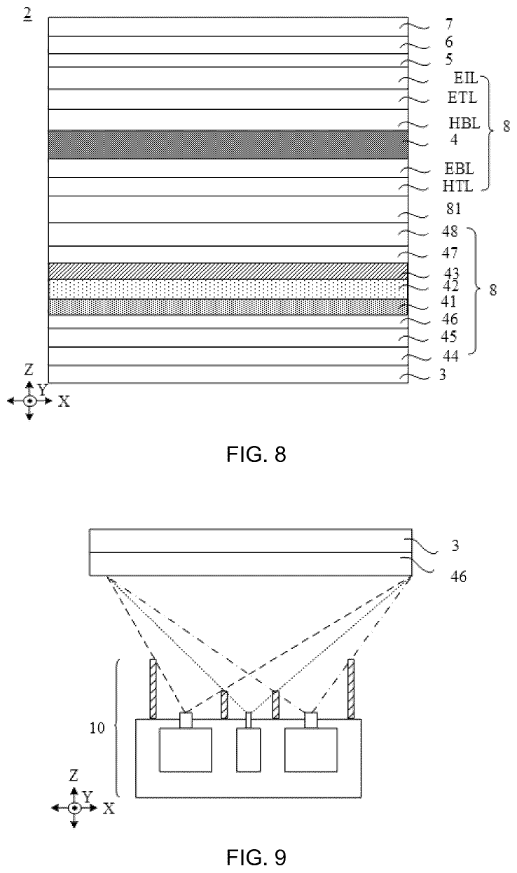

For example, as shown in FIG. 8, the light-emitting unit 8 further includes: a hole transport layer HTL and an electron blocking layer EBL that are located between the charge generation layer 81 and the light-emitting layer 4 and are sequentially stacked on the charge generation layer 81, and a hole blocking layer HBL, an electron transport layer ETL and an electron injection layer EIL that are located between the light-emitting layer and the second electrode and are sequentially stacked on the light-emitting layer. It can be understood that the structures of the hole transport layer HTL, the electron blocking layer EBL, the hole blocking layer HBL, the electron transport layer ETL and the electron injection layer EIL in the light-emitting unit 8 may refer to the description in some of the above embodiments, and details are not repeated here.

The first light-emitting layer 41, the second light-emitting layer 42 and the third light-emitting layer 43 in the light-emitting layer of the light-emitting device 2 provided in some of the above embodiments may be formed by evaporation.

For example, the first light-emitting layer 41, the second light-emitting layer 42 and the third light-emitting layer 43 may be formed separately in three evaporation processes.

As another example, the first light-emitting layer 41 includes a first host material, a first sensitizing material and a first guest material, the second light-emitting layer 42 includes a second host material, a second sensitizing material and a second guest material, the third light-emitting layer 43 includes a third host material, a third sensitizing material and a third guest material, the first host material is the same as the second host material and the third host material, the first sensitizing material is the same as the second sensitizing material and the third sensitizing material, and the first guest material is the same as the second guest material and the third guest material. In this case, the first light-emitting layer 41, the second light-emitting layer 42 and the third light-emitting layer 43 may be formed in a single evaporation process, and the light-emitting layer of the light-emitting device 2 may be formed by a three-source co-evaporation process (FIG. 9 is a simple schematic diagram of a three-source co-evaporation process performed using an evaporation device 10).

In some embodiments, in a case where the first light-emitting layer 41, the second light-emitting layer 42 and the third light-emitting layer 43 all include stabilizing materials, and the stabilizing materials are the same stabilizing material, the light-emitting layer may be formed by four-source co-evaporation using an evaporation device including four evaporation sources.

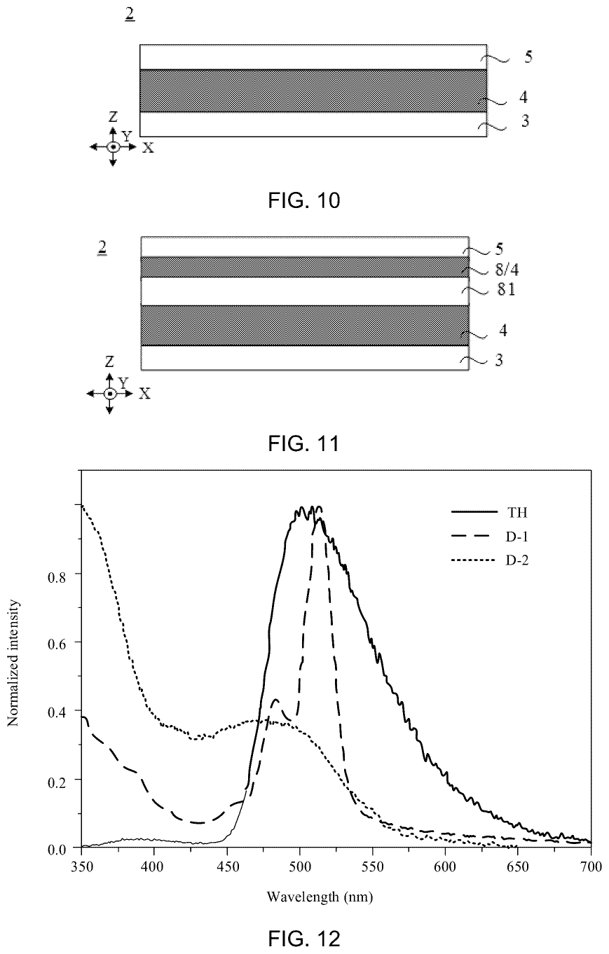

Some embodiments of the present disclosure further provide another light-emitting device. As shown in FIG. 10, the light-emitting device 2 includes a first electrode 3 and a second electrode 5 that are opposite, and a light-emitting layer 4 located between the first electrode 3 and the second electrode 5. A material of the light-emitting layer 4 includes a sensitizing material. In a thickness direction of the light-emitting layer 4 and from the first electrode 3 to the second electrode 5, a mass concentration of the sensitizing material in the light-emitting layer 4 changes from small to large and then from large to small.

For example, the mass concentration of the sensitizing material in the light-emitting layer is not uniform. In the thickness direction of the light-emitting layer 4 and from the first electrode 3 to the second electrode 5, the mass concentration of the sensitizing material in the light-emitting layer 4 gradually increases from small to large, and then gradually decreases from large to small. Alternatively, the mass concentration of the sensitizing material in the light-emitting layer 4 changes from small to large step by step and then changes from large to small step by step.

The material of the light-emitting layer 4 may further include a host material, a guest material and a stabilizing material.

For example, the host material has the same function as the second host material in the above embodiments. The host material may be the same as or different from the second host material in the above embodiments. The sensitizing material has the same function as the second sensitizing material in the above embodiments. The sensitizing material may be the same as or different from the second sensitizing material in the above embodiments. In addition, the guest material has the same function as the second guest material in the above embodiments. The guest material may be the same as or different from the second guest material in the above embodiments.

The light-emitting device 2 provided by the above embodiments of the present disclosure makes the mass concentration of the sensitizing material in the light-emitting layer 4 change from small to large and then from large to small in the thickness direction of the light-emitting layer 4 and from the first electrode 3 to the second electrode 5, so that more sensitizing material may transfer energy to the guest material, which is beneficial to luminescence of the guest material, thereby improving the luminous efficiency of the light-emitting device.

It can be understood that in the thickness direction of the light-emitting layer 4 and from the first electrode 3 to the second electrode 5, the mass concentration of the guest material in the light-emitting layer may be uniform or non-uniform.

In some embodiments, in the thickness direction of the light-emitting layer 4 and from the first electrode 3 to the second electrode 5, the mass concentration of the guest material in the light-emitting layer 4 changes from small to large and then changes from large to small.

Thus, more luminous centers of the guest material may be located inside the light-emitting layer, which is beneficial to improving the luminescence stability of the light-emitting device.

In some embodiments, the material of the light-emitting layer 4 further includes a stabilizing material. In the thickness direction of the light-emitting layer 4, the mass concentration of the stabilizing material in the light-emitting layer 4 is substantially the same.

The mass concentration of the stabilizing material in the light-emitting layer 4 is substantially uniform, that is, the stabilizing material has the same distribution amounts at different positions of the light-emitting layer.

The stabilizing material has the same function as the second stabilizing material in the above embodiments. The stabilizing material may be the same as or different from the second stabilizing material in the above embodiments.

Of course, the light-emitting layer of the light-emitting device provided in the embodiments may also be formed by evaporation.

In some embodiments, as shown in FIG. 11, the light-emitting device 2 further includes a plurality of light-emitting unit 8 disposed between the first electrode 3 and the second electrode 5, and at least one light-emitting unit 8 includes the light-emitting layer 4. The light-emitting device 2 further includes a charge generation layer 81 disposed between two adjacent light-emitting units 8, and the charge generation layer is used to connect the two adjacent light-emitting units 8.

For example, the charge generation layer 81 in the light-emitting device in the embodiments has the same structure as the charge generation layer in the light-emitting device provided in the above embodiments, and reference may be made to the description of the charge generation layer in the above embodiments.

The structure and material composition of the light-emitting layer are the same as those of the light-emitting layer in the above embodiments. Reference may be made to the description of the light-emitting layer in some of the above embodiments, and details are not repeated here.

With the above setting method, the light-emitting layer may absorb light emitted by the adjacent light-emitting layer and be excited to emit light, thereby improving the light extraction efficiency and luminous brightness of the light-emitting device.

In addition, in order to study the luminescence lives and the luminous efficiencies of the light-emitting devices provided in the above embodiments, the inventors produced different light-emitting devices and tested current densities, voltages, luminous efficiencies and luminescence lives of all the light-emitting devices and color coordinates of lights emitted by all the light-emitting devices to obtain Tables 1, 2 and 3.

In Table 1, a light-emitting device 1 is a reference light-emitting device, that is, taking the luminous efficiency of the light-emitting device 1 as 100% and the luminescence life of the light-emitting device 1 as 100% as a reference, relative values of the luminous efficiencies and luminescence lives of light-emitting devices 2 to 13 are calculated.

That is, in the light-emitting devices 1 to 13 in Table 1, each light-emitting device includes an anode, a hole injection layer, a hole transport layer, an electron blocking layer, a hole blocking layer, an electron transport layer, an electron injection layer, a cathode and an optical capping layer.

The anode of each light-emitting device has the same material and the same thickness. The material of the anode is a composite material of silver and ITO, a thickness of silver is 100 nm, and a thickness of ITO is 8 nm. The cathode of each light-emitting device has the same material. The material of the cathode is an alloy of magnesium and silver, and the thickness of the cathode is 15 nm. The hole injection layer of each light-emitting device has the same material and the same thickness.

The hole transport layer of each light-emitting device has the same material and the same thickness. Each hole transport layer includes two hole transport sub-layers, and a highest occupied molecular orbital energy level of a hole transport sub-layer proximate to the hole injection layer is less than a highest occupied molecular orbital energy level of a hole transport sub-layer proximate to the electron blocking layer.

The electron blocking layer of each light-emitting device has the same thickness, which is 5 nm. Except for the material of the electron blocking layer of the light-emitting device 3, the materials of the electron blocking layers of the other light-emitting devices (referring to the light-emitting device 1, the light-emitting device 2 and the light-emitting devices 4 to 13) are the same.

The hole blocking layer of each light-emitting device has the same material and the same thickness. The electron transport layer of each light-emitting device has the same material and the same thickness. The electron injection layer of each light-emitting device has the same material and the same thickness, and the thickness of the electron injection layer of each light-emitting device is 1 nm.

In addition, in Table 1, EM1 represents the first light-emitting layer in the light-emitting device, EML2 represents the second light-emitting layer in the light-emitting device, EML3 represents the third light-emitting layer in the light-emitting device, TM represents a host material, TH represents a sensitizing material, D-1 represents a guest material, and D-2 represents a stabilizing material. Taking the light-emitting device 1 as an example, the thickness of the second light-emitting layer in the light-emitting device 1 is 40 nm, and the material of the second light-emitting layer include three types, namely TM, TH and D-1. A proportion of the mass concentration of the host material in the light-emitting layer, the mass concentration of the sensitizing material in the light-emitting layer and the mass concentration of the guest material in the light-emitting layer is 60%:39%:1%. The first light-emitting layer and the third light-emitting layer are not provided in the light-emitting device 1, and only the second light-emitting layer is provided. Similarly, other light-emitting devices will not be introduced one by one.

TABLE 1

| | | Material | | Material | | Material |
|---|---|---|---|---|---|---|
| | | composition | | composition | | composition |
| | | and mass | | and mass | | and mass |
| | Thickness | concentration | Thickness | concentration | Thickness | concentration |
| Item | of EML1 | of EML1 | of EML2 | of EML2 | of EML3 | of EML3 |
| Light-emitting | / | / | 40 nm | TM:TH:D-1 = | / | / |
| device 1 | | | | 60%:39%:1% | | |
| Light-emitting | 6 nm | TM:D-1 = | 34 nm | TM:TH:D-1 = | / | / |
| device 2 | | 99%:1% | | 60%:39%:1% | | |
| Light-emitting | 6 nm | TM:D-1 = | 35 nm | TM:TH:D-1 = | / | / |
| device 3 | | 99%:1% | | 60%:39%:1% | | |
| Light-emitting | 6 nm | TM:TH = | 34 nm | TM:TH:D-1 = | / | / |
| device 4 | | 65%:35% | | 60%:39%:1% | | |
| Light-emitting | 3 nm | TM:D-1 = | 34 nm | TM:TH:D-1 = | 3 nm | TM |
| device 5 | | 99%:1% | | 60%:39%:1% | | |
| Light-emitting | 3 nm | TM:D-1 = | 34 nm | TM:TH:D-1 = | 3 nm | TM:D-1 = |
| device 6 | | 99%:1% | | 60%:39%:1% | | 99%:1% |
| Light-emitting | 3 nm | TM:D-1 = | 34 nm | TM:TH:D-1 = | 3 nm | TM:TH:D-1 = |
| device 7 | | 99%:1% | | 60%:39%:1% | | 65%:34.2%:0.8% |
| Light-emitting | 3 nm | TM:TH:D-1 = | 34 nm | TM:TH:D-1 = | 3 nm | TM:TH:D-1 = |
| device 8 | | 65%:34.2%:0.8% | | 60%:39%:1% | | 65%:34.2%:0.8% |
| Light-emitting | 3 nm | TM:TH:D-1 = | 34 nm | TM:TH:D-1 = | 3 nm | TM:TH:D-1 = |
| device 9 | | 70%:29.2%:0.8% | | 60%:39%:1% | | 70%:29.2%:0.8% |
| Light-emitting | 3 nm | TM:TH:D-1 = | 34 nm | TM:TH:D-1 = | 3 nm | TM:TH:D-1 = |
| device 10 | | 75%:24.2%:0.8% | | 60%:39%:1% | | 75%:24.2%:0.8% |
| Light-emitting | 3 nm | TM:TH:D-1 = | 34 nm | TM:TH:D-1 = | 3 nm | TM:TH:D-1 = |
| device 11 | | 80%:19.2%:0.8% | | 60%:39%:1% | | 80%:19.2%:0.8% |
| Light-emitting | / | / | 34 nm | TM:TH:D-1 = | 6 nm | TM:TH:D-1 = |
| device 12 | | | | 60%:39%:1% | | 70%:29.2%:0.8% |
| Light-emitting | 3 nm | TM:D-1 = | 34 nm | TM:TH:D-1 = | 6 nm | TM:TH:D-1:D-2 = |
| device 13 | | 99%:1% | | 65%:34%:1% | | 65%:33.6%:0.8%:0.6% |

TABLE 2

| | | | | | PL peak |
|---|---|---|---|---|---|
| | HOMO(eV) | LUMO (eV) | T1 (eV) | S1 (eV) | (nm) |
| TM | −5.9 | −2.6 | 2.7 | 3.3 | 350 |
| TH | −6.0 | −3.6 | 2.52 | 2.57 | 510 |
| D-1 | −5.8 | −3.4 | 2.1 | 2.4 | 525 |
| D-2 | −5.8 | −3.5 | 2.40 | 2.46 | 575 |
| EBL-1 | −5.7 | / | 2.65 | / | / |
| EBL-2 | −5.65 | / | 2.5 | / | / |
| HBL | −6.4 | / | 2.59 | / | / |

Table 2 shows molecular energy levels of materials of light-emitting layers of a plurality of light-emitting devices in Table 1, where S1 represents a molecular ground state energy level of the material, LUMO represents a lowest unoccupied molecular orbital energy level of the material, and PL peak refers to a wavelength of the photoemission spectrum peak of the material. The host material TM is a hole-type material, and a ratio of the hole mobility thereof to the electron mobility thereof is greater than or equal to 20. EBL-1 represents the material of the electron blocking layers in the light-emitting devices 1 to 2 and the light-emitting devices 4 to 13. EBL-2 represents the material of the electron blocking layer in the light-emitting device 3. HBL represents the material of the hole blocking layers in the light-emitting devices 1 to 12.

It can be seen that the host material TM and the sensitizing material TH have different HOMO energy levels, different LUMO energy levels, different T1, different S1 and different PL peaks. An absolute value of the HOMO energy level of the host material TM is less than an absolute value of the HOMO energy level of the sensitizing material TH, an absolute value of the T1 energy level of the host material TM is greater than an absolute value of the T1 energy level of the sensitizing material TH, and a wavelength of the PL peak of the host material TM is less than a wavelength of the PL peak of the sensitizing material TH.

In addition, the inventors also tested the emission spectrum of the sensitizing material TH, and the absorption spectra of the guest material D-1 and the stabilizing material D-2. Specifically, the emission spectrum of the sensitizing material TH is obtained under a test condition that a doped film is formed with a ratio of the mass concentration of the host material TM to the mass concentration of the guest material TH being 90%: 10% and the excitation spectrum wavelength for the doped film is 350 nm. The absorption spectrum of the guest material D-1 was measured for a film made of the guest material D-1 with the mass concentration of 100%. Similarly, the absorption spectrum of the stabilizing material D-2 was measured for a film made of the stabilizing material D-2 with the mass concentration of 100%. The emission spectrum and absorption spectra are plotted to obtain FIG. 12.

It can be seen from FIG. 12 that an overlapping area between a normalized emission spectrum of the sensitizing material TH and a normalized absorption spectrum of the guest material D-1 is greater than or equal to 60% of an integrated area of the normalized absorption spectrum of the guest material D-1. Therefore, in the light-emitting layers of the light-emitting devices 1 to 13, more light emitted by the sensitizing material may be absorbed by the guest material and the guest material can be excited to emit more light, thereby improving the luminous efficiency of the light-emitting device. Moreover, an overlapping area between the normalized emission spectrum of the sensitizing material and a normalized absorption spectrum of the stabilizing material is greater than or equal to 30% of an integrated area of the normalized absorption spectrum of the stabilizing material. Therefore, it can be ensured that the stabilizing material absorbs excess excitons generated by the sensitizing material, thereby ensuring the luminescence stability of the light-emitting device and prolonging the luminescence life of the light-emitting device.

TABLE 3

| Light- | Current | | | Color | |
|---|---|---|---|---|---|
| emitting | density | Voltage | Efficiency | coordinates | |
| device | (mA/cm²) | (V) | (cd/A) | (CIE-1931) | LT90 Life |
| Light- | 15 | 3.95 | 100% | 0.227, 0.738 | 100% |
| emitting | | | | | |
| device 1 | | | | | |
| Light- | 15 | 3.80 | 98.0% | 0.224, 0.740 | 103% |
| emitting | | | | | |
| device 2 | | | | | |
| Light- | 15 | 3.85 | 97.8% | 0.224, 0.740 | 105% |
| emitting | | | | | |
| device 3 | | | | | |
| Light- | 15 | 3.90 | 104.2% | 0.226, 0.738 | 108% |
| emitting | | | | | |
| device 4 | | | | | |
| Light- | 15 | 3.94 | 96.8% | 0.220, 0.741 | 31% |
| emitting | | | | | |
| device 5 | | | | | |
| Light- | 15 | 3.98 | 77.9% | 0.232, 0.733 | 37% |
| emitting | | | | | |
| device 6 | | | | | |
| Light- | 15 | 3.93 | 100% | 0.228, 0.737 | 95% |
| emitting | | | | | |
| device 7 | | | | | |
| Light- | 15 | 3.92 | 102.5% | 0.233, 0.734 | 103% |
| emitting | | | | | |
| device 8 | | | | | |
| Light- | 15 | 3.96 | 107.9% | 0.224, 0.740 | 95% |
| emitting | | | | | |
| device 9 | | | | | |
| Light- | 15 | 3.99 | 110.4% | 0.227, 0.737 | 91% |
| emitting | | | | | |
| device 10 | | | | | |
| Light- | 15 | 4.02 | 109.6% | 0.227, 0.737 | 85% |
| emitting | | | | | |
| device 11 | | | | | |
| Light- | 15 | 4.0 | 106.5% | 0.226, 0.738 | 80% |
| emitting | | | | | |
| device 12 | | | | | |
| Light- | 15 | 3.98 | 99.1% | 0.230, 0.736 | 107% |
| emitting | | | | | |
| device 13 | | | | | |

In combination with Tables 1, 2 and 3, the host material of the first light-emitting layer in the light-emitting device 2 has a relatively high mass concentration, and the host material is a hole-type host material with a relatively high triplet state. The host material of the first light-emitting layer is also doped with a guest material. A third light-emitting layer is not provided in the light-emitting device 2. The luminous efficiency of the light-emitting device 2 is 98%, and the luminescence life is 103%. Compared with the light-emitting device 1, the luminous efficiency of the light-emitting device 2 is reduced. However, since the first light-emitting layer has a host material with a high triplet state, the first light-emitting layer basically plays a role of blocking excitons in the second light-emitting layer. Therefore, there is no special requirement for the triplet state of the electron blocking layer in the structure of the light-emitting device 2, so that the light-emitting device provided by the embodiments of the present disclosure has an advantage of flexible material selection. As shown in the light-emitting device 3, the EBL1 in the original light-emitting device 2 is replaced by the EBL2, the luminous efficiency of the light-emitting device 3 changes slightly, and the luminescence life is also prolonged to a certain extent. Moreover, compared with the light-emitting device 1, the light-emitting device 2 and the light-emitting device 3 have relatively low operating voltages, thereby reducing the power consumption of the light-emitting device and saving energy. The color coordinates of lights emitted by the light-emitting device 2 and the light-emitting device 3 have a slight difference from the color coordinates of the light emitted by the light-emitting device 1.

The light-emitting device 4 has a first light-emitting layer and a second light-emitting layer. The first light-emitting layer includes a host material and a sensitizing material, and the mass concentration 35% of the sensitizing material in the first light-emitting layer is less than the mass concentration 39% of the sensitizing material in the second light-emitting layer. The luminous efficiency of the light-emitting device 4 is 104.2%, and the luminescence life thereof is 108%. Compared with the light-emitting device 1, both the luminous efficiency and the luminescence life are improved, and the operating voltage of the light-emitting device 4 is also reduced, thereby reducing the power consumption of the light-emitting device 4.

The light-emitting devices 5 to 7 each have a first light-emitting layer composed of a host material and a guest material, and the mass concentrations of the host material and the guest material in the first light-emitting layer of each light-emitting device are the same. The light-emitting devices 5 to 7 each have a second light-emitting layer composed of a host material, a sensitizing material and a guest material, and the mass concentrations of the host material, the sensitizing material and the guest material in the second light-emitting layer of each light-emitting device are the same. The third light-emitting layer of the light-emitting device 5 includes only a host material, the third light-emitting layer of the light-emitting device 6 includes a host material and a guest material, and the third light-emitting layer of the light-emitting device 7 includes a host material, a sensitizing material and a guest material.

The material of the third light-emitting layer in the light-emitting device 5 is the host material TM, and the host material TM is a hole-type host material. The third light-emitting layer is not conducive to transport of the electrons to the second light-emitting layer, so that the electrons accumulated in the second light-emitting layer have a small number, which is prone to reduction of the luminescence life of the light-emitting device. Similarly, the material of the third light-emitting layer in the light-emitting device 6 is the host material TM and the guest material D-1, which is not conducive to transport of the electrons from the third light-emitting layer to the second light-emitting layer, thereby reducing the luminescence life of the light-emitting device 6. The material of the third light-emitting layer in the light-emitting device 7 further includes a sensitizing material TH in addition to the host material and the guest material, and the sensitizing material TH is an electron-type material, which is conducive to transport of the electrons from the third light-emitting layer to the second light-emitting layer, thereby improving the luminous efficiency and the luminescence life of the light-emitting device.

Specifically, the luminous efficiency of the light-emitting device 5 is 96.8%, which is slightly reduced compared with the light-emitting device 1. The luminescence life of the light-emitting device 5 is 31%, which is significantly reduced compared with the light-emitting device 1. The luminous efficiency of the light-emitting device 6 is 77.9%, which is significantly reduced compared with the light-emitting device 1. The luminescence life of the light-emitting device 6 is 37%, which is significantly reduced compared with the light-emitting device 1. The luminous efficiency of the light-emitting device 7 is 100%, which is unchanged compared with the light-emitting device 1. The luminescence life of the light-emitting device 7 is 95%, which is slightly reduced compared with the light-emitting device 1.

The light-emitting devices 8 to 11 each include a first light-emitting layer, a second light-emitting layer and a third light-emitting layer, and the mass concentration of the sensitizing material TH in each of the first light-emitting layer and the third light-emitting layer is less than the mass concentration of the sensitizing material in the second light-emitting layer. From the light-emitting device 8 to the light-emitting device 11, the mass concentrations of the sensitizing materials in the first light-emitting layers (or the third light-emitting layers) decrease successively, namely 34.2%, 29.2%, 24.2% and 19.2%.

The sensitizing material TH is an electron-type material. The sensitizing material in the third light-emitting layer is beneficial to transport of electrons from the third light-emitting layer to the second light-emitting layer, thereby improving the luminous efficiency and luminescence life of the light-emitting device. The greater the mass concentration of the sensitizing material TH, the more the energy can be transferred, and the longer the luminescence life of the light-emitting device. Therefore, as the mass concentration of the sensitizing material in the first light-emitting layer decreases, the luminous efficiency of the light-emitting device may be improved (from the light-emitting device 8 to the light-emitting device 11, the luminous efficiencies are 102.5%, 107.9%, 110.4% and 109.6% sequentially), the luminescence lives of the light-emitting devices have a certain decrease (from the light-emitting device 8 to the light-emitting device 11, the luminescence lives are 103%, 95%, 91% and 85% sequentially), and the operating voltages of the light-emitting devices gradually increase (from the light-emitting device 8 to the light-emitting device 11, the operating voltages are 3.92, 3.96, 3.99 and 4.02 sequentially).

The difference between the mass concentration of the sensitizing material in the first light-emitting layer and the mass concentration of the sensitizing material in the second light-emitting layer should not be too large, so as to avoid adverse effects on the life of the light-emitting device. For example, the difference between the mass concentration of the sensitizing material in the first light-emitting layer and the mass concentration of the sensitizing material in the second light-emitting layer is less than or equal to 15%. The mass concentration of the sensitizing material of the second light-emitting layer in the light-emitting device 11 is 39%, the mass concentration of the sensitizing material of the first light-emitting layer is 19.2%, and the difference between the two is about 20%, so that the luminescence life of the light-emitting device 11 is 85% of the luminescence life of the light-emitting device 1, and the luminescence life has a relatively large loss. The mass concentration of the sensitizing material of the second light-emitting layer in the light-emitting device 8 is 39%, the mass concentration of the sensitizing material of the first light-emitting layer is 34.2%, and the difference between the two is about 5%, which is a small difference. As a result, the light-emitting device 8 has a higher luminous efficiency and a longer luminescence life than the light-emitting device 1.

The light-emitting device 12 includes a second light-emitting layer and a third light-emitting layer, and the material of the third light-emitting layer includes a host material TM, a sensitizing material TH and a guest material D-1. Compared with the light-emitting device 1, the luminous efficiency of the light-emitting device 12 is 105.1%, and the luminescence life of the light-emitting device 12 is 80%. The luminous efficiency is improved, and the luminescence life is significantly reduced. Compared with the light-emitting device 12, the light-emitting device 9 includes a first light-emitting layer, and the light-emitting device 9 has a longer luminescence life. It can be seen that the provision of the first light-emitting layer may prolong the luminescence life of the light-emitting device.

The light-emitting device 13 includes a first light-emitting layer, a second light-emitting layer and a third light-emitting layer. The material of the third light-emitting layer includes a host material, a guest material, a sensitizing material and a stabilizing material. The stabilizing material may inhibit quenching of triplet excitons in the light-emitting layer, thereby improving the stability of the light-emitting device and further prolonging the luminescence life of the light-emitting device. Specifically, the luminescence life of the light-emitting device 13 is 107% of that of the light-emitting device 1, and the luminous efficiency of the light-emitting device 13 is 99.1% of that of the light-emitting device 1. In addition, compared with the light-emitting device 7, the third light-emitting layer of the light-emitting device 13 contains a stabilizing material, and the luminescence life of the light-emitting device 13 is prolonged compared with the light-emitting device 7. Therefore, the stabilizing material in the light-emitting layer may improve the stability of the light-emitting device, thereby improving the luminescence life of the light-emitting device.

In addition, the inventors also explored the luminous efficiency and the luminescence life of the light-emitting device with the series structure. Specifically, a light-emitting device 14 is set as a reference light-emitting device, and the light-emitting device 14 includes an anode, a hole injection layer, a hole transport layer, an electron blocking layer, a light-emitting layer A, a hole blocking layer, a charge generation layer, a hole transport layer, an electron blocking layer, a light-emitting layer B, an electron injection layer, a cathode and an optical capping layer that are stacked in sequence. A light-emitting device 15 includes an anode, a hole injection layer, a hole transport layer, an electron blocking layer, a light-emitting layer C, a hole blocking layer, a charge generation layer, a hole transport layer, an electron blocking layer, a light-emitting layer D, an electron injection layer, a cathode and an optical capping layer that are stacked in sequence. The materials and the thicknesses of the anode, the hole injection layer, the hole transport layer, the electron blocking layer, the hole blocking layer, the hole transport layer, the electron blocking layer and the cathode in each of the light-emitting device 14 and the light-emitting device 15 are respectively the same as those of the light-emitting device 1 in the above embodiments. In the light-emitting device 14, the thickness of the light-emitting layer A is 40 nm, the material of the light-emitting layer A includes a host material, a sensitizing material and a guest material, and a proportion of the mass concentrations of the host material, the sensitizing material and the guest material is 60%: 39%: 1%; the thickness of the light-emitting layer B and the material composition of the light-emitting layer B are respectively the same as those of the light-emitting layer A. In the light-emitting device 15, the light-emitting layer C includes a first light-emitting layer, a second light-emitting layer and a third light-emitting layer. The thickness of the first light-emitting layer is 3 nm, the material of the first light-emitting layer includes a host material TM, a sensitizing material TH and a guest material D-1, and a proportion of the mass concentrations of the host material TM, the sensitizing material TH and the guest material D-1 is 70%: 29.2%: 0.8%; the thickness of the second light-emitting layer is 34 nm, the material of the second light-emitting layer include a host material TM, a sensitizing material TH and a guest material D-1, and a proportion of the mass concentrations of the host material TM, the sensitizing material TH and the guest material D-1 is 60%: 39%: 1%; the thickness of the third light-emitting layer is equal to the thickness of the first light-emitting layer, and the material composition and the proportion of the mass concentrations of the third light-emitting layer are the same as the material composition and the proportion of the mass concentrations of the first light-emitting layer. The light-emitting layer D in the light-emitting device 15 has the same composition as the light-emitting layer C thereof. The luminous efficiencies and the luminescence lives of the light-emitting device 14 and the light-emitting device 15 were tested, and results are shown in Table 4.

TABLE 4

| Light- | Current | | | Color | |
|---|---|---|---|---|---|
| emitting | density | Voltage | Efficiency | coordinates | |
| device | (mA/cm²) | (V) | (cd/A) | (CIE-1931) | LT90 Life |
| Light- | 10 | 7.50 | 100% | 0.224, 0.740 | 100% |
| emitting | | | | | |
| device 14 | | | | | |
| Light- | 10 | 7.63 | 117% | 0.232, 0.733 | 96% |
| emitting | | | | | |
| device 15 | | | | | |

It can be seen from Table 4 that compared with the light-emitting device 14, the light-emitting device 15 has a decreased operating voltage, a greatly improved luminous efficiency and a little changed luminescence life, and color coordinates of light emitted by the light-emitting device have little change. Therefore, a series-connected light-emitting device provided by the embodiments of the present disclosure has a high luminous efficiency and a low operating voltage, thereby reducing the power consumption of the light-emitting device.

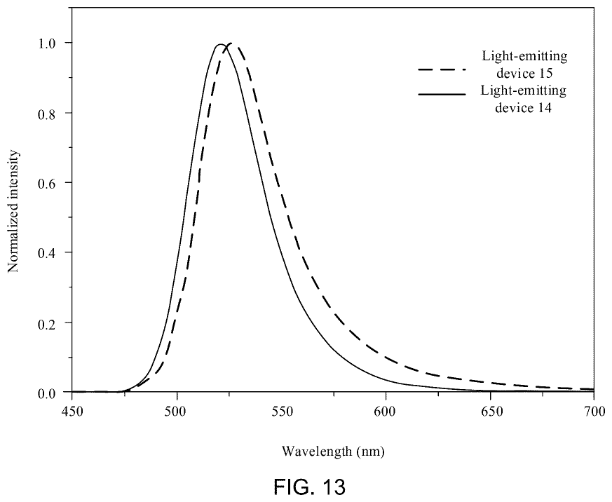

The inventors also tested an intensity of light emitted by the light-emitting device 14 and an intensity of light emitted by the light-emitting device 15 to obtain FIG. 13.

It can be seen from FIG. 13 that a wavelength of light with the highest intensity emitted by the light-emitting device 15 is close to a wavelength of light with the highest intensity emitted by the light-emitting device 14, and a normalized area of the light emitted by the light-emitting device 15 is larger than a normalized area of the light emitted by the light-emitting device 14. Therefore, the light-emitting device 15 has a higher luminous efficiency than the light-emitting device 14. It can be seen combined with Table 4 that the luminous efficiency of the light-emitting device 15 is 117% of that of the light-emitting device 14.

It can be understood that beneficial effects that can be achieved by the display substrate and the display apparatus provided in some embodiments of the present disclosure are the same as the beneficial effects that can be achieved by the light-emitting device provided in some of the above embodiments, and details are not repeated here.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising: a first electrode, at least one first light-emitting layer, at least one second light-emitting layer, at least one third light-emitting layer and a second electrode that are disposed sequentially, wherein
in a first light-emitting layer, a second light-emitting layer and a third light-emitting layer, at least the second light-emitting layer includes a sensitizing material;
a mass concentration X2 of the sensitizing material in a material of the second light-emitting layer and a mass concentration X1 of the sensitizing material in a material of the first light-emitting layer satisfy: X2≥X1 and X1≥0; and
the mass concentration X2 of the sensitizing material in the material of the second light-emitting layer and a mass concentration X3 of the sensitizing material in a material of the third light-emitting layer satisfy: X2>X3 and X3≥0.

2. The light-emitting device according to claim 1, wherein the mass concentration X2 of the sensitizing material in the material of the second light-emitting layer satisfies: 20%≤X2≤70%; and/or
the mass concentration X1 of the sensitizing material in the material of the first light-emitting layer satisfies: 3%≤X1≤50%; and/or
the mass concentration X3 of the sensitizing material in the material of the third light-emitting layer satisfies: 3%≤X3≤50%.

3. The light-emitting device according to claim 2, wherein the mass concentration X2 of the sensitizing material in the material of the second light-emitting layer and the mass concentration X1 of the sensitizing material in the material of the first light-emitting layer satisfy: 0≤(X2-X1)≤15%;
the mass concentration X2 of the sensitizing material in the material of the second light-emitting layer and the mass concentration X3 of the sensitizing material in the material of the third light-emitting layer satisfy: 0≤(X2−X3)≤15%.

4. (canceled)

5. (canceled)

6. The light-emitting device according to claim 1, wherein in the first light-emitting layer, the second light-emitting layer and the third light-emitting layer, at least the second light-emitting layer includes a guest material;
a mass concentration Y2 of the guest material in the material of the second light-emitting layer and a mass concentration Y1 of the guest material in the material of the first light-emitting layer satisfy: Y2>Y1 and Y1≥0; and
the mass concentration Y2 of the guest material in the material of the second light-emitting layer and a mass concentration Y3 of the guest material in the material of the third light-emitting layer satisfy: Y2>Y3 and Y3≥0.

7. The light-emitting device according to claim 6, wherein the mass concentration Y2 of the guest material in the material of the second light-emitting layer satisfies:
$$0.1 \% \leq Y 2 \leq 5 \% .$$

8. The light-emitting device according to claim 6, wherein the sensitizing material included in the second light-emitting layer is a second sensitizing material, the guest material included in the second light-emitting layer is a second guest material; and the second light-emitting layer further includes a second host material and a second stabilizing material; and
a difference between a triplet state of at least one of the second host material, the second sensitizing material and the second guest material and a triplet state of the second stabilizing material is less than or equal to 0.3 eV; and/or
an overlapping area between a normalized emission spectrum of at least one of the second host material, the second sensitizing material and the second guest material and a normalized absorption spectrum of the second stabilizing material is greater than or equal to 30% of an integrated area of the normalized absorption spectrum of the second stabilizing material.

9. The light-emitting device according to claim 8, wherein a mass concentration of the second stabilizing material in the material of the second light-emitting layer is less than or equal to 5%;
a wavelength of a photoemission spectrum peak of the second host material is less than a wavelength of a photoemission spectrum peal of the second sensitizing material, the wavelength of the photoemission spectrum peak of the second sensitizing material is less than a wavelength of a photoemission spectrum peak of the second stabilizing material; and a wavelength of a photoemission spectrum peak of the second guest material is less than the wavelength of the photoemission spectrum peak of the second stabilizing material.

10. (canceled)

11. The light-emitting device according to claim 6, wherein the sensitizing material included in the third light-emitting layer is a third sensitizing material; the guest material included in the second light-emitting layer is a second guest material; and the sensitizing material included in the first light-emitting layer is a first sensitizing material; and
an overlapping area between a normalized emission spectrum of the third sensitizing material and a normalized absorption spectrum of the second guest material is greater than or equal to 60% of an integrated area of the normalized absorption spectrum of the second guest material; and/or
an overlapping area between a normalized emission spectrum of the first sensitizing material and a normalized absorption spectrum of the second guest material is greater than or equal to 60% of an integrated area of the normalized absorption spectrum of the second guest material.

12. The light-emitting device according to claim 11, wherein an overlapping area between a normalized emission spectrum of the second guest material and a normalized emission spectrum of the light-emitting device is greater than or equal to 80% of an integrated area of the normalized emission spectrum of the second guest material; and/or
the sensitizing material included in the second light-emitting layer is a second sensitizing material, and an overlapping area between a normalized emission spectrum of the second sensitizing material and the normalized absorption spectrum of the second guest material is greater than or equal to 60% of an integrated area of the normalized absorption spectrum of the second guest material.

13. (canceled)

14. The light-emitting device according to claim 1, wherein the sensitizing material included in the first light-emitting layer is a first sensitizing material; and the first light-emitting layer further includes a first host material, a first stabilizing material and a first guest material; and
a difference between a triplet state of at least one of the first host material, the first guest material and the first sensitizing material and a triplet state of the first stabilizing material is less than or equal to 0.3 eV; and/or
an overlapping area between a normalized emission spectrum of at least one of the first host material, the first guest material and the first sensitizing material and a normalized absorption spectrum of the first stabilizing material is greater than or equal to 30% of an integrated area of the normalized absorption spectrum of the first stabilizing material.

15. The light-emitting device according to claim 14,
wherein the sensitizing material included in the second light-emitting layer is a second sensitizing material; the second light-emitting layer further includes a second host material; the sensitizing material included in the third light-emitting layer is a third sensitizing material; and the third light-emitting layer further includes a third host material;
a highest occupied molecular orbital energy level of the first host material is HOMO(A), a highest occupied molecular orbital energy level of the first sensitizing material is HOMO(B), a highest occupied molecular orbital energy level of the second host material is HOMO(E), a highest occupied molecular orbital energy level of the second sensitizing material is HOMO(F), a highest occupied molecular orbital energy level of the third host material is HOMO(J), and a highest occupied molecular orbital energy level of the third sensitizing material is HOMO(K); and HOMO(A), HOMO(B), HOMO(E), HOMO(F), HOMO(J) and HOMO(K) satisfy:
$$\vert HOMO ( A ) \vert \leq \vert HOMO ( B ) \vert , \vert HOMO ( E ) \leq \vert HOMO ( F ) \vert ,$$
$$\vert HOMO ( J ) \vert \leq \vert HOMO ( K ) \vert , \vert HOMO ( A ) \vert \leq \vert HOMO ( F ) \vert ,$$
$$\vert HOMO ( E ) \vert \leq \vert HOMO ( K ) \vert , \vert HOMO ( A ) - HOMO ( E ) \vert \leq 0.25 eV ,$$
$$\vert HOMO ( E ) - H O M O ( J ) \vert \leq 0.25 eV , \vert HOM O ( A ) - H O M O ( B ) \vert \leq 0.25 eV ,$$
$$\vert HOMO ( E ) - H O M O ( F ) \vert \leq 0.25 eV , \vert HOM O ( J ) - H O M O ( K ) \vert \leq 0.25 eV ,$$
$$\vert HOMO ( A ) - H O M O ( F ) \vert \leq 0.25 eV and$$
$$\vert HOMO ( E ) - H O M O ( K ) \vert \leq 0.25 eV .$$

16. The light-emitting device according to claim 15, wherein a triplet state of the first host material is T1(A), a triplet state of the first sensitizing material is T1(B), a triplet state of the second host material is T1(E), a triplet state of the second sensitizing material is T1(F), a triplet state of the third host material is T1(J), and a triplet state of the third sensitizing material is T1(K); and T1(A), T1(B), T1(E), T1(F), T1(J) and T1(K) satisfy:
$$\vert T 1 ( A ) - T 1 ( E ) \vert \leq 0.15 eV , \vert T 1 ( E ) - T 1 ( J ) \vert \leq 0.15 eV ;$$
$$T 1 ( A ) \geq T 1 ( B ) , T 1 ( E ) \geq T 1 ( F ) and T 1 ( J ) \geq T 1 ( K ) .$$

17. The light-emitting device according to claim 1, wherein an electroluminescence amount of the second light-emitting layer is greater than or equal to 50% of a total luminescence amount of the light-emitting device.

18. The light-emitting device according to claim 1, wherein a thickness L1 of the first light-emitting layer, a thickness L2 of the second light-emitting layer and a thickness L3 of the third light-emitting layer satisfy: L2>L1 and L2>L3; and/or
a thickness L1 of the first light-emitting layer, a thickness L2 of the second light-emitting layer a thickness L3 of the light-emitting layer satisfy: L2≥(L1+L3).

19. (canceled)

20. The light-emitting device according to claim 1, further comprising: an electron blocking layer located between the first electrode and the first light-emitting layer, wherein
the sensitizing material included in the first light-emitting layer is a first sensitizing material; and a triplet state of the electron blocking layer is greater than a triplet state of the first sensitizing material; and/or
the light-emitting device further comprising: a hole blocking layer located between the second electrode and the third light-emitting layer, where
the sensitizing material included in the third light-emitting layer is a third sensitizing material; and a triplet state of the hole blocking layer is grater than a triplet state of the third sensitizing material.

21. (canceled)

22. The light-emitting device according to claim 1, wherein the light-emitting device comprises a plurality of light-emitting units stacked between the first electrode and the second electrode, each light-emitting unit includes a first light-emitting layer, a second light-emitting layer and a third light-emitting layer; and
the light-emitting device further comprises a charge generation layer disposed between two adjacent light-emitting units, and the charge generation layer is used to connect the two adjacent light-emitting units.

23. A light-emitting device, comprising: a first electrode and a second electrode that are disposed oppositely, and light-emitting layer located between the first electrode and the second electrode, wherein
a material of a light-emitting layer includes a sensitizing material; and
in a thickness direction of the light-emitting layer and from the first electrode to the second electrode, a mass concentration of the sensitizing material in the light-emitting layer changes from small to large and then from large to small.

24. The light-emitting device according to claim 23,
wherein the material of the light-emitting layer further includes a guest material; and in the thickness direction of the light-emitting layer and from the first electrode to the second electrode, a mass concentration of the guest material in the light-emitting layer changes from small to large and then from large to small; and/or
the material of the light-emitting layer further includes a stabilizing material; and in the thickness direction of the light-emitting layer, a mass concentration of the stabilizing material in the light-emitting layer is substantially the same.

25. (canceled)

26. (canceled)

27. A display substrate, comprising:
the light-emitting device according to claim 1; and
a back plate electrically connected to the light-emitting device.

28. A display apparatus, comprising: the display substrate according to claim 27, and a driver chip electrically connected to the display substrate.
